(19) United States
(12) Patent Application Publication
(10) Pub. No.: US 2024/0218135 A1
(43) Pub. Date: Jul. 4, 2024

(54) PROTECTIVE FILM AND LAMINATE

(71) Applicant: FUJIFILM Corporation, Tokyo (JP)

(72) Inventors: Keigo YAMAGUCHI, Shizuoka (JP); Kunihiko KODAMA, Shizuoka (JP)

(73) Assignee: FUJIFILM Corporation, Tokyo (JP)

(21) Appl. No.: 18/424,886

(22) Filed: Jan. 29, 2024

Related U.S. Application Data
(63) Continuation of application No. PCT/JP2022/031339, filed on Aug. 19, 2022.

(30) Foreign Application Priority Data
Aug. 31, 2021 (JP) 2021-140779
Feb. 9, 2022 (JP) 2022-018732

(51) Int. Cl. C08J 5/18; C08F 212/08

(52) U.S. Cl. CPC C08J 5/18; C08F 212/08; C08J 2325/14

(57) ABSTRACT

The present invention provides a protective film having excellent adhesiveness to an electrode and excellent moisture-heat resistance, and a laminate. The protective film of the present invention is a protective film for an electrode, containing a polymer A which has a repeating unit A having an acid group, in which an acid value of the protective film is 120 mgKOH/g or less, the protective film has a maximal absorption wavelength in a wavelength range of 300 to 400 nm, and in a case where the protective film is heated at 140° C. for 30 minutes, a rate of change of K (an absorption coefficient)/S (a scattering coefficient) at the maximal absorption wavelength is 10% or less.

### CROSS-REFERENCE TO RELATED APPLICATIONS

This application is a Continuation of PCT International Application No. PCT/JP2022/031339 filed on Aug. 19, 2022, which claims priority under 35 U.S.C. § 119(a) to Japanese Patent Application No. 2021-140779 filed on Aug. 31, 2021 and Japanese Patent Application No. 2022-018732 filed on Feb. 9, 2022. The above applications are hereby expressly incorporated by reference, in their entirety, into the present application.

### BACKGROUND OF THE INVENTION

### 1. Field of the Invention

The present invention relates to a protective film and a laminate.

### 2. Description of the Related Art

In a display device provided with a touch panel such as a capacitive input device (for example, an organic electroluminescent display device, a liquid crystal display device, and the like), an electrode pattern such as a wiring line for a peripheral wiring portion and a lead-out wiring portion corresponding to a sensor in a visual recognition portion is provided inside the touch panel.

In many cases, a protective film is used in order to protect the above-described electrode pattern. As a method for forming the protective film on the electrode pattern, for example, a method of forming a photosensitive layer using a photosensitive material, and a method of using a transfer film having a temporary support and a photosensitive layer formed of a photosensitive material, in which the number of steps to obtain a pattern shape is small, has been widely used. Examples of the method of forming the pattern using the transfer film include a method of exposing and developing a photosensitive layer transferred from a transfer film onto any base material through a mask having a predetermined pattern shape.

As the protective film, for example, WO2013/084886A discloses a protective film formed of a “photosensitive resin composition containing, on a base material, a binder polymer having a carboxyl group in which an acid value is 75 mgKOH/g or more, a photopolymerizable compound, and a photopolymerization initiator” and a “photosensitive element including a support film and a photosensitive layer consisting of the photosensitive resin composition, which is provided on the support film”.

### SUMMARY OF THE INVENTION

A protective film for an electrode is required to be excellent in both adhesiveness to an electrode and moisture-heat resistance. The excellent moisture-heat resistance means that the electrode is less likely to be discolored in a case where the protective film and the electrode are brought into contact with each other and stored for a certain period of time under conditions of constant temperature and humidity.

The present inventors have found that, in a case where a protective film is formed on an electrode using the photosensitive material or the like as disclosed in WO2013/084886A, it is difficult to achieve both the adhesiveness to an electrode and the moisture-heat resistance.

Therefore, an object of the present invention is to provide a protective film having excellent adhesiveness to an electrode and excellent moisture-heat resistance. Another object of the present invention is to provide a laminate.

As a result of intensive studies to achieve the above-described objects, the present inventors have found that the above-described objects can be achieved by the following configurations, and have completed the present invention.

(1) A protective film for an electrode, comprising:
a polymer A which has a repeating unit A having an acid group,
in which an acid value of the protective film is 120 mgKOH/g or less,
the protective film has a maximal absorption wavelength in a wavelength range of 300 to 400 nm, and
in a case where the protective film is heated at 140° C. for 30 minutes, a rate of change of K (an absorption coefficient)/S (a scattering coefficient) at the maximal absorption wavelength is 10% or less.

(2) The protective film according to (1),
in which the acid value of the protective film is 100 mgKOH/g or less.

(3) The protective film according to (1) or (2),
in which the acid value of the protective film is 80 mgKOH/g or less.

(4) The protective film according to any one of (1) to (3),
in which, in the case where the protective film is heated at 140° C. for 30 minutes, the K/S at the maximal absorption wavelength is 4.0 or less.

(5) The protective film according to any one of (1) to (4),
in which, in the case where the protective film is heated at 140° C. for 30 minutes, the K/S at the maximal absorption wavelength is 0.01 or more.

(6) The protective film according to any one of (1) to (5),
in which the polymer A has a group formed by removing one hydrogen atom from a nitrogen-containing aromatic compound, and
the nitrogen-containing aromatic compound has a maximal absorption wavelength in the wavelength range of 300 to 400 nm.

(7) The protective film according to any one of (1) to (6),
in which the polymer A has a group represented by Formula (Zb2) described later.

(8) The protective film according to any one of (1) to (7),
in which the repeating unit A has a repeating unit represented by Formula (a1) described later or a repeating unit represented by Formula (a2) described later.

(9) The protective film according to any one of (1) to (8),
in which the acid value of the protective film is 5 mgKOH/g or more.

(10) A laminate comprising, in the following order:
a substrate;
an electrode; and
the protective film according to any one of (1) to (9).

According to the present invention, it is possible to provide a protective film having excellent adhesiveness to an electrode and excellent moisture-heat resistance. In addition, it is also possible to provide a laminate.

### BRIEF DESCRIPTION OF THE DRAWINGS

FIG. 1 is a schematic view showing an example of a layer configuration of a transfer film according to an embodiment.

### DESCRIPTION OF THE PREFERRED EMBODIMENTS

Hereinafter, the present invention will be described in detail.

In the present specification, meaning of each notation is as follows.

A numerical range represented using “to” means a range including numerical values described before and after the preposition “to” as a lower limit and an upper limit.

In a numerical range described in a stepwise manner, an upper limit or a lower limit described in a certain numerical range may be replaced with an upper limit or a lower limit in another numerical range described in a stepwise manner, or may be replaced with a value described in Examples.

A term “step” includes not only an independent step but also a step that cannot be clearly distinguished from other steps, as long as the intended purpose of the step is achieved.

A temperature condition may be set to 25° C. unless otherwise specified. For example, unless otherwise specified, a temperature at which each of the above-described steps is performed may be 25° C.

“Transparent” means that an average transmittance of visible light having a wavelength of 400 nm to 700 nm is 80% or more, preferably 90% or more. For example, a “transparent resin layer” means a resin layer having an average transmittance of visible light having a wavelength of 400 to 700 nm is 80% or more.

In addition, the average transmittance of visible light can be measured using a spectrophotometer. For example, the measurement can be performed using a spectrophotometer U-3310 (manufactured by Hitachi, Ltd.).

“Actinic ray” or “radiation” means, for example, a bright line spectrum of a mercury lamp such as g-rays, h-rays and i-rays, far ultraviolet rays typified by an excimer laser, extreme ultraviolet rays (EUV light), X-rays, electron beams (EB), or the like. In addition, “light” means an actinic ray or radiation.

Unless otherwise specified, “exposure” includes exposure by a mercury lamp, far ultraviolet rays typified by an excimer laser, extreme ultraviolet rays, X-rays, EUV light, or the like, and also includes exposure of drawing by corpuscular beams such as electron beams and ion beams.

Unless otherwise specified, a molecular weight in a case of a molecular weight distribution is a weight-average molecular weight. In addition, a weight-average molecular weight of a resin is a weight-average molecular weight obtained by performing polystyrene conversion of a value measured by gel permeation chromatography (GPC).

“(Meth)acrylic acid” is a concept including both acrylic acid and methacrylic acid, and “(meth)acryloyl group” is a concept including both an acryloyl group and a methacryloyl group.

“Alkali-soluble” refers to that a dissolution rate obtained by the following method is 0.01 m/sec or more.

A propylene glycol monomethyl ether acetate solution having a concentration of an object (for example, a resin or the like) of 25% by mass is applied to a glass substrate, and then heated in an oven at 100° C. for 3 minutes to obtain a coating film of the object (thickness: 2.0 μm). The above-described coating film is immersed in a 1% by mass aqueous solution of sodium carbonate (liquid temperature: 30° C.), thereby obtaining the dissolution rate (m/sec) of the above-described coating film.

In a case where the object is not dissolved in propylene glycol monomethyl ether acetate, the object is dissolved in an organic solvent (for example, tetrahydrofuran, toluene, ethanol, and the like) having a boiling point of lower than 200° C., other than propylene glycol monomethyl ether acetate.

“Water-soluble” means that solubility in 100 g of water having a liquid temperature of 22° C. and a pH of 7.0 is 0.1 g or more. For example, “water-soluble resin” means a resin which satisfies the above-described solubility conditions.

“Solid content” of a photosensitive material means components which form a photosensitive layer formed of the photosensitive material, and in a case where the photosensitive material contains a solvent (for example, an organic solvent, water, and the like), the solid content means all components except the solvent. In addition, in a case where the components are components which form a photosensitive layer, the components are considered to be solid contents even in a case where the components are liquid components.

Unless otherwise specified, a thickness of each layer is an average thickness measured using a scanning electron microscope (SEM) in a case where the thickness is 0.5 m or more, and is an average thickness measured using a transmission electron microscope (TEM) in a case where the thickness is less than 0.5 m. The above-described average thickness is an average thickness obtained by forming a section to be measured using an ultramicrotome, measuring thicknesses of any five points, and arithmetically averaging the values.

Unless otherwise specified, a refractive index is a value measured with an ellipsometer at a wavelength of 550 nm.

Unless otherwise specified, a boiling point means a boiling point at 1 atm (standard boiling point).

### [Protective Film]

The protective film according to the embodiment of the present invention is a protective film for an electrode, containing
a polymer A which has a repeating unit A having an acid group,
in which an acid value of the protective film is 120 mgKOH/g or less,
the protective film has a maximal absorption wavelength in a wavelength range of 300 to 400 nm, and
in a case where the protective film is heated at 140° C. for 30 minutes, a rate of change of K (an absorption coefficient)/S (a scattering coefficient) at the maximal absorption wavelength is 10% or less.

Detailed mechanism of the action by which the desired effect of the present invention is obtained with the protective film according to the embodiment of the present invention is not clear, but the present inventors have presumed as follows.

Feature points of the protective film according to the embodiment of the present invention are, for example, that the protective film contains the polymer A, that the acid value of the protective film is a predetermined value or less, that the protective film has a specific maximal absorption wavelength described later, and that the rate of change of K (absorption coefficient)/S (scattering coefficient) at the specific maximal absorption wavelength is 10% or less.

Since the protective film contains the polymer A which has a repeating unit A having an acid group, the electrode and the acid group in the polymer A interact with each other, and adhesiveness to the electrode can be improved. In addition, since the acid value of the protective film is a predetermined value or less, deterioration of moisture-heat resistance can be suppressed while maintaining the adhesiveness. On the other hand, a case where the protective film has a specific maximal absorption wavelength gives suggestions of the presence of a predetermined structure in the protective film (for example, a group formed by removing one hydrogen atom from a compound B described later, a repeating unit derived from the compound B described later, and the like), and the moisture-heat resistance can be improved due to interaction the structure and the electrode and improvement of packing properties between the polymers A in the protective film. Further, since the rate of change of K (absorption coefficient)/S (scattering coefficient) at the specific maximal absorption wavelength is low, it is presumed that the above-described predetermined structure is fixed to the polymer A, so that the moisture-heat resistance is easily improved.

Hereinafter, the fact that at least one effect of the adhesiveness to an electrode or the moisture-heat resistance is more excellent is also referred to as “effect of the present invention is more excellent”.

Hereinafter, various components which can be contained in the protective film will be described in detail.

### [Polymer A]

The protective film contains a polymer A.

The polymer A has a repeating unit A having an acid group.

Some or all of acid groups included in the polymer A may or may not be anionized in the protective film. In the present specification, the “acid group” is a concept including both an anionic acid group and a non-anionic acid group.

Specifically, a part or all of carboxy groups which can be included in the polymer A may or may not be anionized in the protective film. In the present specification, the “carboxy group” is a concept including both an anionic carboxy group (—COO⁻) and a non-anionic carboxy group (—COOH).

### <Repeating Unit A>

The repeating unit A is a repeating unit having an acid group.

A content of the repeating unit A is not particularly limited, and is adjusted such that the acid value of the protective film, which will be described later, is within a predetermined range. The content of the repeating unit A is preferably 15% by mass or less, more preferably 12% by mass or less, still more preferably 10% by mass or less, and particularly preferably 8% by mass or less with respect to the total mass of the protective film. The lower limit thereof is often more than 0% by mass, and it is preferably 1% by mass or more with respect to the total mass of the protective film.

The acid group included in the repeating unit A is preferably a proton dissociative group having a pKa of 12 or less. Specific examples thereof include a carboxy group, a sulfonamide group, a phosphonic acid group, a sulfo group, a phenolic hydroxy group, and a sulfonylimide group, and a carboxy group is preferable.

(Repeating Unit Having Carboxy Group)

The repeating unit A is preferably a repeating unit having a carboxy group.

It is preferable that the repeating unit having a carboxy group has at least one or more selected from the group consisting of a repeating unit represented by Formula (a1) and a repeating unit represented by Formula (a2).

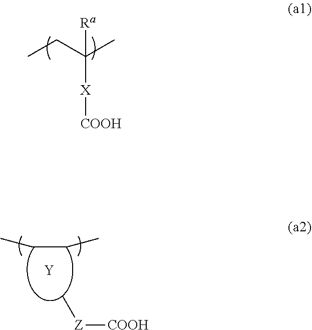

In Formula (a1), Ra represents a hydrogen atom or a substituent, and X represents a single bond or a divalent linking group having 1 or more carbon atoms.

In Formula (a2), Y represents a ring group having 2 or more carbon atoms, and Z represents a single bond or a divalent linking group.

R^{a} represents a hydrogen atom or a substituent.

Examples of the above-described substituent include an alkyl group, an alkoxycarbonyl group, and a hydroxyalkyl group.

The above-described alkyl group may be linear or branched. The number of carbon atoms in the above-described alkyl group is preferably 1 to 5 and more preferably 1 to 3.

As an alkyl group constituting the above-described alkoxycarbonyl group and the above-described hydroxyalkyl group, the above-described alkyl group is preferable.

X represents a single bond or a divalent linking group having 1 or more carbon atoms.

Examples of the divalent linking group having 1 or more carbon atoms include —CO—, —COO—, —NR^{NA}— (R^{NA} represents an alkyl group having 1 to 5 carbon atoms), a divalent hydrocarbon group, a divalent linking group X1 selected from groups of a combination of these groups, and a divalent linking group X2 formed from the divalent linking group X1 and a divalent linking group selected from —O—, —S—, —NH—, and a group of a combination of these groups.

As the divalent linking group having 1 or more carbon atoms, an alkylene group, an arylene group, —COO—, an amide linking group, a carbonate linking group, a urethane linking group, a urea linking group, a divalent linking group Y1 selected from groups of a combination of these groups, or a divalent linking group Y2 formed from the divalent linking group Y1 and a divalent linking group selected from —O—, —S—, —NH—, and a divalent linking group of a combination of these groups is preferable; and an alkylene group, a cycloalkylene group, an arylene group, —COO—, or a divalent linking group of a combination of these groups is more preferable.

The above-described divalent linking group having 1 or more carbon atoms may further have a substituent. Examples of the substituent include a hydroxy group, an alkyl group, and a halogen atom.

The number of carbon atoms in the divalent linking group having 1 or more carbon atoms is 1 or more, preferably 1 to 30, more preferably 1 to 10, and still more preferably 1 to 8.

The above-described divalent hydrocarbon group as the divalent linking group having 1 or more carbon atoms may be linear, branched, or cyclic.

The number of carbon atoms in the above-described divalent hydrocarbon group is preferably 1 to 30, more preferably 1 to 20, and still more preferably 1 to 10.

Examples of the above-described divalent hydrocarbon group include arylene groups such as an alkylene group, a cycloalkylene group, an alkenylene group, and a phenylene group, and an alkylene group, a cycloalkylene group, or an arylene group is preferable.

The divalent linking group having 1 or more carbon atoms is preferably an alkylene group A.

The alkylene group A is a linear alkylene group having 1 to 7 carbon atoms, which may have a substituent, and “—CH₂—CH₂—” in the alkylene group may be substituted with “—CO—O—” or “—CH═CH—”. In addition, in a case of having a plurality of substituents, two or more substituents may be bonded to each other to form a ring.

Examples of the above-described substituent include an alkyl group, an alkenylene group, an alkoxy group, an aryl group, a halogen atom, and a hydroxy group.

Specifically, in a case where the alkylene group A is “—CH₂—CH₂—CH₂—CH₂—CH₂—COOH”, it may be “—CO—O—CH₂—CH₂—CH₂—COOH” or “—CH═CH—CH₂—CH₂—CH₂—COOH”. In addition, as shown below, a substituent R¹ and a substituent R² in the alkylene group A may be bonded to each other to form a ring.

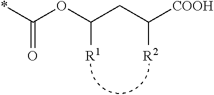

In addition, the alkylene group A is preferably a group represented by Formula (a3).

*-L¹-L³-L²-COOH (a3)

In Formula (a3), L¹ represents a single bond or —CH₂—, L² represents —(CR^{a1}R^{a2})ₙ—, a phenylene group which may have a substituent, a norbornane ring which may have a substituent, or a cyclohexane ring which may have a substituent, R^{a1} and R^{a2} each independently represent a hydrogen atom or a methyl group, n represents an integer of 1 to 3, L³ represents a single bond, a phenylene group which may have a substituent, *1-COO-*2, or *1-OCO-*2. *1 represents a bonding position to L¹, *2 represents a bonding position to L², * represents a bonding position, and in a case of a plurality of R^{a1}'s or R^{a2}'s, R^{a1}'s or R^{a2}'s may be the same or different from each other.

In Formula (a2), Y represents a ring group having 2 or more carbon atoms.

The above-described ring may be a monocycle or a polycycle.

The above-described ring group is preferably an alicyclic ring group.

The number of carbon atoms in the alicyclic ring group is preferably 1 or more, more preferably 1 to 30, still more preferably 3 to 20, and particularly preferably 3 to 15.

Examples of a ring constituting the alicyclic ring group include a cyclopentane ring, a cyclohexane ring, a dicyclopentane ring, an isobornane ring, an adamantane ring, a tricyclodecane ring, a tricyclodecene ring, norbornane ring, an isophorone ring, and a ring of a combination of these rings.

The alicyclic ring group may further have a substituent. The above-described substituent is preferably an alkyl group or an alkenyl group.

The alicyclic ring group may have a heteroatom.

As the heteroatom, a nitrogen atom, an oxygen atom, or a sulfur atom is preferable. A position where the heteroatom is introduced may be any of a ring member atom or a position other than the ring member atom. Specifically, a carbon atom in methylene constituting the ring of the alicyclic ring may be replaced with —O—, —CO—, —NR^{N}— (R^{N} represents a hydrogen atom or an alkyl group having 1 to 5 carbon atoms), or a group of a combination of these groups. In addition, examples of the position where the heteroatom is introduced, other than the ring member atom, include introduction into a substituent included in the alicyclic ring.

Examples of the alicyclic ring having a heteroatom include an imide ring such as a succinimide ring.

Z represents a single bond or a divalent linking group.

Examples of the above-described divalent linking group include the divalent linking group having 1 or more carbon atoms, represented by X in Formula (a1), —O—, —S—, —NH—, and a divalent linking group of a combination of these groups, and the divalent linking group having 1 or more carbon atoms, represented by X, is preferable.

Examples of the repeating unit A include the following repeating units.

In the formulae, R¹ and R² each independently represent a hydrogen atom or a methyl group.

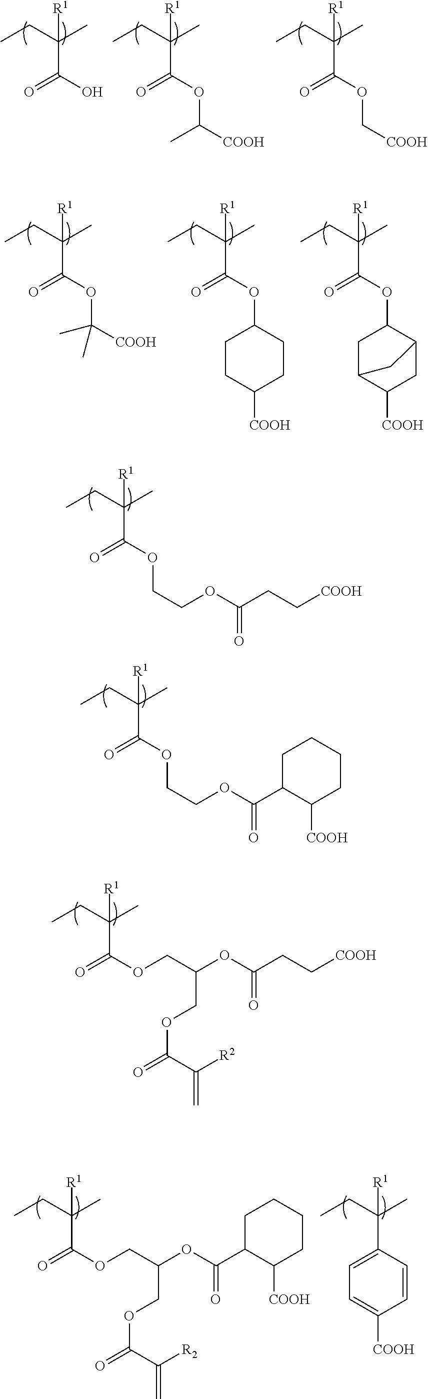

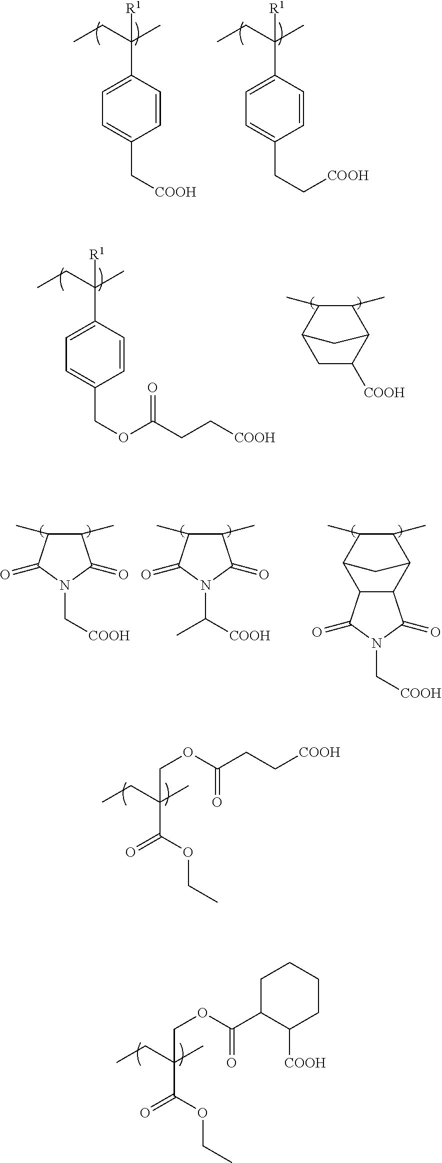

Examples of a monomer from which the repeating unit having a carboxy group is derived include (meth)acrylic acid, crotonic acid, itaconic acid, maleic acid, and fumaric acid, and from the viewpoint of pattern formability, (meth)acrylic acid is preferable. That is, the repeating unit having a carboxy group is preferably a repeating unit derived from (meth)acrylic acid. A content of the repeating unit having an acid group (preferably, the repeating unit having a carboxy group) in the polymer A is preferably 1 mol % or more and more preferably 5 mol % or more with respect to all repeating units of the polymer A. The upper limit thereof is often 100 mol % or less, preferably 65 mol % or less and more preferably 45 mol % or less with respect to all repeating units of the polymer A.

A content of the repeating unit having an acid group (preferably, the repeating unit having a carboxy group) in the polymer A is preferably 1% by mass or more and more preferably 5% by mass or more with respect to all repeating units of the polymer A. The upper limit thereof is often less than 100% by mass, preferably 70% by mass or less and more preferably 50% by mass or less with respect to all repeating units of the polymer A.

<Repeating Unit B Derived from Compound B>

The polymer A preferably has a repeating unit B derived from a compound B in addition to the above-described repeating unit.

The compound B will be described later.

The polymer A preferably has a structure derived from the compound B, and it is preferably a group formed by removing one or two or more hydrogen atoms from the compound B and more preferably a group formed by removing one hydrogen atom from the compound B.

The structure derived from the compound B may be present in a main chain of the polymer A or may be present in a side chain of the polymer A, and it is preferable to be present in the side chain of the polymer A. In a case where the structure derived from the compound B is present in the side chain, the structure derived from the compound B is bonded to the main chain of the polymer A through a single bond or a linking group.

The above-described compound B is preferably a nitrogen-containing aromatic compound (a compound having a nitrogen atom as a heteroatom of a heteroaromatic ring). The above-described compound B from which the repeating unit B is derived preferably has a specific maximal absorption wavelength.

Among these, the polymer A preferably has a group represented by Formula (Zb1) described later, and more preferably has a group represented by Formula (Zb2) described later.

More specifically, the repeating unit B is preferably a repeating unit represented by Formula (b1), and more preferably a repeating unit represented by Formula (b2).

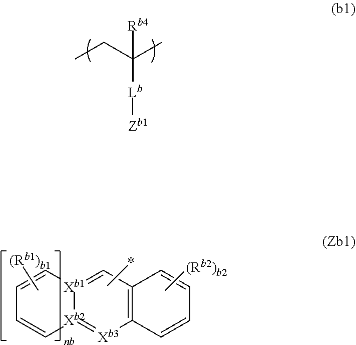

In Formula (b1), L^{b} represents a single bond or a divalent linking group, Z^{b1} represents a group represented by Formula (Zb1), and R^{b4} represents a hydrogen atom or an alkyl group.

In Formula (Zb1), nb represents 0 or 1, in a case where nb represents 0, X^{b1} to X^{b3} each independently represent a nitrogen atom or CR^{b}s, in which at least one of X^{b1}, X^{b2}, or X^{b3} represents a nitrogen atom, in a case where nb represents 1, X^{b1} and X^{b2} represents a carbon atom, and X^{b3} represents a nitrogen atom, R^{b1} and R^{b2} each independently represent a substituent, b1 and b2 each independently represent an integer of 0 to 4, * represents a bonding position, and CR^{b5} represents a hydrogen atom or a substituent.

L^{b} represents a single bond or a divalent linking group.

Examples of the above-described divalent linking group include —O—, —S—, —CO—, —COO—, —CONR^{N}—, an alkylene group, a cycloalkylene group, an alkenylene group, an arylene group, and a divalent linking group of a combination of these groups. R^{N} represents a hydrogen atom or a substituent.

L^{b} is preferably a single bond.

Z^{b}I represents a group represented by Formula (Zb1).

nb represents 0 or 1.

In a case where nb represents 0, X^{b1} to X^{b3} each independently represent a nitrogen atom or CR^{b}s, in which at least one of X^{b1}, X^{b2}, or X^{b3} represents a nitrogen atom. Among these, it is preferable that one of X^{b1}, X^{b2}, or X^{b3} represents a nitrogen atom, and the rest represents CR^{b5}.

In a case where nb represents 1, X^{b1} and X^{b2} represents a carbon atom, and X^{b3} represents a nitrogen atom.

R^{b1} and R^{b2} each independently represent a substituent.

The above-described substituent is preferably an alkyl group, an aryl group, or a group of a combination of these groups, and more preferably an alkyl group.

The above-described alkyl group may be linear, branched, or cyclic. The number of carbon atoms in the above-described alkyl group is preferably 1 to 5.

The above-described aryl group may be monocyclic or polycyclic. The number of carbon atoms in the above-described aryl group is preferably 6 to 12.

In a case of a plurality of R^{b1}'s, R^{b1}'s may be the same or different from each other. In a case of a plurality of R^{b2}'s, R^{b2}'s may be the same or different from each other.

R^{b4} represents a hydrogen atom or an alkyl group.

The above-described alkyl group may be linear, branched, or cyclic. The number of carbon atoms in the above-described alkyl group is preferably 1 to 5.

R^{b}s represents a hydrogen atom or a substituent.

Examples of the substituent represented by R^{b5} include the group exemplified as the substituent represented by R^{b1} and R^{b2} (for example, an alkyl group).

b1 and b2 each independently represent an integer of 0 to 4.

b1 and b2 are preferably an integer of 0 to 2 and more preferably 0 or 1.

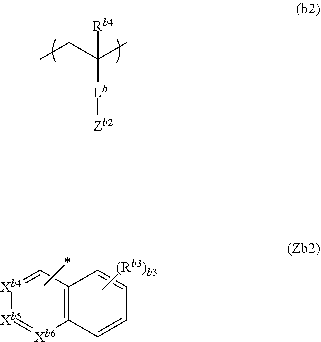

In Formula (b2), L^{b} represents a single bond or a divalent linking group, Z^{b2} represents a group represented by Formula (Zb2), and R^{b4} represents a hydrogen atom or an alkyl group.

In Formula (Zb2), X^{b4} to X^{b6} each independently represent CR^{b6} or a nitrogen atom, at least one of X^{b4}, X^{b5}, or X^{b6} represents a nitrogen atom, R^{b3} represents an alkyl group, R^{b6} represents a hydrogen atom or an alkyl group, b3 represents an integer of 0 to 4, and * represents a bonding position.

R^{b4} and L^{b} in Formula (b2) have the same definitions as R^{b4} and L^{b} in Formula (b1), and suitable aspects thereof are also the same.

Z^{b2} represents a group represented by Formula (Zb2). X^{b4} to X^{b6} each independently represent CR^{b6} or a nitrogen atom. At least one of X^{b4}, X^{b5}, or X^{b6} represents a nitrogen atom.

It is preferable that one of X^{b4}, X^{b5}, or X^{b6} represents a nitrogen atom, and the rest represents CR^{b6}.

R^{b3} represents an alkyl group.

The above-described alkyl group may be linear, branched, or cyclic.

The number of carbon atoms in the above-described alkyl group is preferably 1 to 5. In a case of a plurality of R^{b3}'s, R^{b3}'s may be the same or different from each other.

R^{b6} represents a hydrogen atom or an alkyl group.

The above-described alkyl group may be linear, branched, or cyclic. The number of carbon atoms in the above-described alkyl group is preferably 1 to 5.

b3 represents an integer of 0 to 4.

b3 is preferably an integer of 0 to 2, more preferably 0 or 1, and still more preferably 0.

As Z^{b1} in Formula (b1) and Z^{b2} in Formula (b2), a group represented by any one of Formula (Zba), . . . , or (Zbd) is preferable.

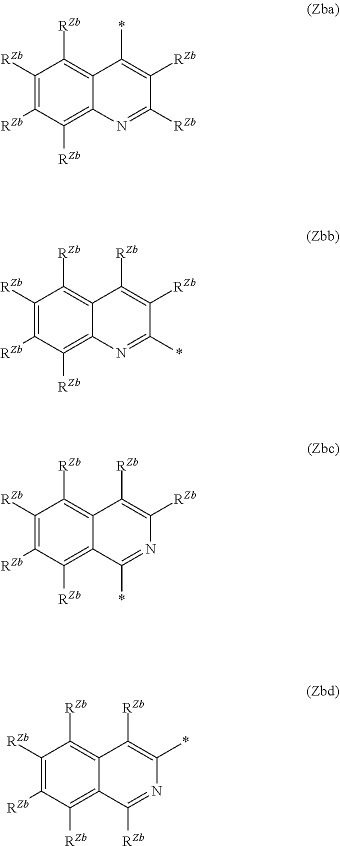

In Formulae (Zba) to (Zbd), R^{Zb} represents a hydrogen atom or an alkyl group, and * represents a bonding position.

The above-described alkyl group has the same definition as the alkyl group represented by R^{b3} in Formula (Zb2), and a suitable aspect thereof is also the same.

A plurality of R^{Z}b's may be the same or different from each other.

In Formula (Zba), it is preferable that at least one of R^{Zb}'s represents a hydrogen atom, it is more preferable that at least four of R^{Zb}'s represent hydrogen atoms, and it is still more preferable that all R^{Zb}'s represent hydrogen atoms.

In Formula (Zbb), it is preferable that at least one of R^{Zb}'s represents a hydrogen atom, it is more preferable that at least four of R^{Zb}'s represent hydrogen atoms, and it is still more preferable that all R^{Zb}'s represent hydrogen atoms.

In Formula (Zbc), it is preferable that at least one of R^{Zb}'s represents a hydrogen atom, it is more preferable that at least four of R^{Zb}'s represent hydrogen atoms, and it is still more preferable that all R^{Zb}'s represent hydrogen atoms.

In Formula (Zbd), it is preferable that at least one of R^{Zb}'s represents a hydrogen atom, it is more preferable that at least four of R^{Zb}'s represent hydrogen atoms, and it is still more preferable that all R^{Zb}'s represent hydrogen atoms.

Examples of the repeating unit B include the following repeating units.

In the formulae, R^{b} represents a substituent, b represents an integer of 0 to 8, and In a case of a plurality of R^{b}'s, R^{b}'s may be the same or different from each other.

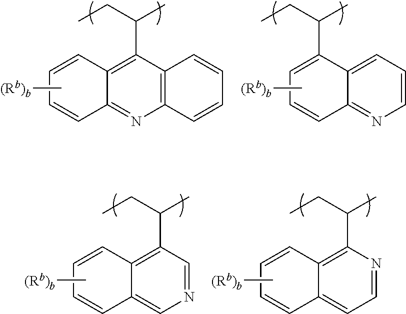

A content of the repeating unit B is preferably 3 to 75 mol %, more preferably 5 to 60 mol %, and still more preferably 10 to 50 mol % with respect to all repeating units of the polymer A.

The content of the repeating unit B is preferably 1% to 75% by mass, more preferably 3% to 60% by mass, and still more preferably 5% to 30% by mass with respect to all repeating units of the polymer A.

As a method of synthesizing the polymer A having the repeating unit B, a known synthesis method can be used. Specific examples thereof include a method of polymerizing a monomer from which the repeating unit A is derived and a monomer from which the repeating unit B is derived, and a synthesis method in which a photosensitive layer is formed of a photosensitive material containing a polymer P described later and the compound B, and then the photosensitive layer is exposed to light to react in a protective film system. The synthesis method using the above-described photosensitive material will be described later in detail in the method for manufacturing a laminate.

### <Repeating Unit Having Aromatic Ring>

The polymer A preferably has a repeating unit having an aromatic ring, in addition to the above-described repeating units.

As the above-described aromatic ring, an aromatic hydrocarbon ring is preferable.

Examples of the repeating unit having an aromatic ring include a repeating unit derived from (meth)acrylate having an aromatic ring, and a repeating unit derived from styrene or a polymerizable styrene derivative.

Examples of the (meth)acrylate having an aromatic ring include benzyl (meth)acrylate, phenethyl (meth)acrylate, and phenoxyethyl (meth)acrylate.

Examples of the styrene and the polymerizable styrene derivative include methylstyrene, vinyltoluene, tert-butoxystyrene, acetoxystyrene, 4-vinylbenzoic acid, styrene dimer, and styrene trimer.

As the repeating unit having an aromatic ring, a repeating unit represented by Formula (C) is preferable.

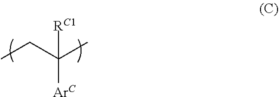

In Formula (C), R^{C1} represents a hydrogen atom, a halogen atom, or an alkyl group, and Ar^{C} represents a phenyl group or a naphthyl group.

R^{C1} represents a hydrogen atom, a halogen atom, or an alkyl group.

Examples of the above-described halogen atom include a fluorine atom, a chlorine atom, a bromine atom, and an iodine atom.

The above-described alkyl group may be linear or branched. The number of carbon atoms in the above-described alkyl group is preferably 1 to 5 and more preferably 1.

Ar^{C} represents a phenyl group or a naphthyl group.

The above-described phenyl group and the above-described naphthyl group may further have a substituent. Examples of the above-described substituent include an alkyl group, an alkoxy group, an aryl group, a halogen atom, and a hydroxy group.

Ar^{C} is preferably a phenyl group.

Examples of the repeating unit having an aromatic ring include the following repeating units.

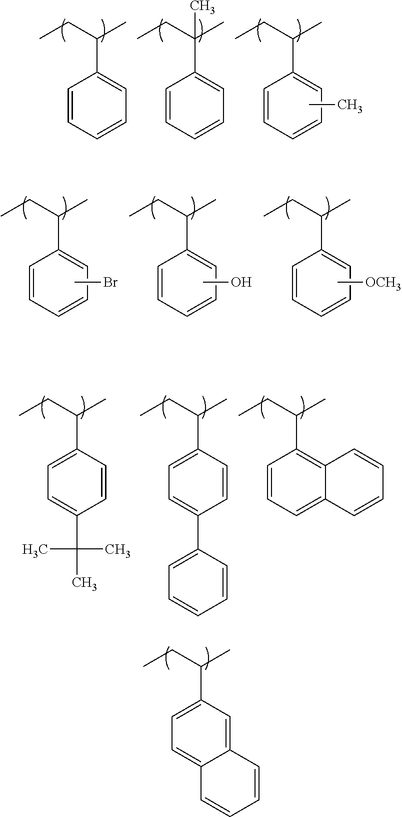

A content of the repeating unit having an aromatic ring in the polymer A is preferably 5 to 80 mol %, more preferably 15 to 75 mol %, and still more preferably 30 to 70 mol % with respect to all repeating units of the polymer A.

The content of the repeating unit having an aromatic ring in the polymer A is preferably 5% to 90% by mass, more preferably 10% to 80% by mass, and still more preferably 30% to 70% by mass with respect to all repeating units of the polymer A.

### <Repeating Unit Having Alicyclic Structure>

The polymer A preferably has a repeating unit having an alicyclic structure, in addition to the above-described repeating units.

The alicyclic structure may be monocyclic or polycyclic. Examples of the alicyclic structure include a dicyclopentanyl ring structure, a dicyclopentenyl ring structure, an isobornyl ring structure, an adamantane ring structure, and a cyclohexyl ring structure.

Examples of a monomer from which the repeating unit having an alicyclic structure is derived include dicyclopentanyl (meth)acrylate, dicyclopentenyl (meth)acrylate, isobornyl (meth)acrylate, adamantyl (meth)acrylate, and cyclohexyl (meth)acrylate.

A content of the repeating unit having an alicyclic structure in the polymer A is preferably 3 to 70 mol %, more preferably 5 to 60 mol %, and still more preferably 10 to 55 mol % with respect to all repeating units of the polymer A.

The content of the repeating unit having an alicyclic structure in the polymer A is preferably 3% to 90% by mass, more preferably 5% to 70% by mass, and still more preferably 20% to 60% by mass with respect to all repeating units of the polymer A.

### <Other Repeating Units>

The polymer A may have other repeating units in addition to the above-described repeating units.

Examples of the other repeating units include a repeating unit derived from an alkyl (meth)acrylate such as methyl (meth)acrylate, and a repeating unit derived from an alkylene compound such as ethylene.

An alkyl group in the alkyl (meth)acrylate may be linear, branched, or cyclic. The above-described alkyl group may further have a substituent. A hydroxy group is preferable as the above-described substituent. The number of carbon atoms in the above-described alkyl group is preferably 1 to 50 and more preferably 1 to 10.

An alkylene group in the alkylene compound such as ethylene may be linear, branched, or cyclic. The above-described alkylene group may further have a substituent. A hydroxy group is preferable as the above-described substituent. The number of carbon atoms in the above-described alkylene group is preferably 2 to 10 and more preferably 2 to 3.

A content of the other repeating units in the polymer A is preferably 1 to 70 mol %, more preferably 2 to 50 mol %, and still more preferably 3 to 20 mol % with respect to all repeating units of the polymer A.

The content of the other repeating units in the polymer A is preferably 1% to 70% by mass, more preferably 1% to 50% by mass, and still more preferably 1% to 35% by mass with respect to all repeating units of the polymer A.

A weight-average molecular weight of the polymer A is preferably 5,000 or more, more preferably 10,000 or more, and still more preferably 15,000 or more. The upper limit thereof is preferably 50,000 or less.

The polymer A may be used alone or in combination of two or more kinds thereof.

A content of the polymer A is preferably 10% to 100% by mass, more preferably 30% to 100% by mass, and still more preferably 50% to 100% by mass with respect to the total mass of the protective film.

### [Other Components]

The protective film may contain other components in addition to the above-described polymer A.

Examples of the other components include various components contained in the photosensitive material described later (for example, the compound B and the like). Specific examples of the above-described reactant include a cured substance between polymerizable compounds described later.

### [Physical Properties of Protective Film]

### <Acid Value>

The acid value of the protective film is 120 mgKOH/g or less, and from the viewpoint that the moisture-heat resistance of the protective film is more excellent, it is preferably 100 mgKOH/g or less, more preferably 80 mgKOH/g or less, and still more preferably 50 mgKOH/g or less. The lower limit thereof is not particularly limited, and is often more than 0 mgKOH/g and more often 5 mgKOH/g or more.

Examples of a method for measuring the above-described acid value of the protective film include the following method.

First, a predetermined amount (approximately 20 mg) of a sample is scraped off from the protective film, the obtained sample is freeze-pulverized, N-methyl-2-pyrrolidone (NMP) (150 μL) is added thereto, and the mixture is stirred in an aqueous solution of lithium carbonate (Li₂CO₃) (1.2 g/100 mL; lithium carbonate is dissolved in ultrapure water and then filtered through a filter) for 6 days. After the stirring, particles are sedimented by ultracentrifugal treatment (140,000 rpm for 30 minutes), the obtained sediment is replaced five times with ultrapure water, and the obtained sediment is dried to obtain an analysis sample. Using ICP-OES (Optima 7300DV manufactured by PerkinElmer Inc.), an amount of lithium (Li) per 1 g of the obtained analysis sample is analyzed. Since H of the acid group is substituted with Li according to the above-described procedure, the amount of Li corresponds to the number of acid groups. The obtained numerical value is divided by the number of atoms of Li (6.941 g/mol) to calculate the amount (mol/g) of acid groups in the protective film, and the obtained numerical value is multiplied by the molecular weight of KOH to calculate the acid value (mgKOH/g) of the protective film. By carrying out the measurement of the acid value of the protective film 5 times, and removing the maximum value and the minimum value among the obtained measured values for the 5 times, the remaining three measured values are arithmetically averaged, and the resulting arithmetic value is defined as the acid value (mgKOH/g) of the protective film according to the embodiment of the present invention. That is, in the present invention, the acid value of the protective film, which is the above-described arithmetic average value, may be 120 mgKOH/g or less.

The above-described analysis of the Li amount is carried out according to the following procedure. Approximately 1.5 to 2 mg of the above-described analysis sample is weighed, a 60% by mass of HNO₃ aqueous solution (5 mL) is added thereto, and MW Teflon (registered trademark) ashing (microwave sample decomposition device UltraWAVE max: 260° C.) is performed. Ultrapure water is added to the ashed analysis sample to be 50 mL, and the Li amount is quantified by an absolute calibration curve method using ICP-OES.

### <Maximal Absorption Wavelength>

The protective film has a maximal absorption wavelength in a wavelength range of 300 to 400 nm (specific maximal absorption wavelength).

It is sufficient that the protective film has the specific maximal absorption wavelength, and the protective film may have a maximal absorption wavelength in another wavelength range. The specific maximal absorption wavelength is preferably in a wavelength range of 300 to 380 nm, more preferably in a wavelength range of 310 to 360 nm, and still more preferably in a wavelength range of 310 to 330 nm.

The protective film may have a plurality of specific maximal absorption wavelengths in the wavelength range of 300 to 400 nm. In a case where the protective film has a plurality of maximal absorption wavelengths, it is preferable that any specific maximal absorption wavelength is within the above-described range.

The fact that the protective film has the specific maximal absorption wavelength means that the protective film has a predetermined structure. The above-described predetermined structure is preferably a structure derived from the repeating unit B or the compound B, and more preferably a structure derived from the repeating unit B or the nitrogen-containing aromatic compound.

The specific maximal absorption wavelength is determined according to a procedure of a method for measuring the rate of change of K (absorption coefficient)/S (scattering coefficient), which will be described later.

### <Rate of Change of K (Absorption Coefficient)/S (Scattering Coefficient)>

In a case where the protective film is heated at 140° C. for 30 minutes, the rate of change of K (an absorption coefficient)/S (a scattering coefficient) at the specific maximal absorption wavelength is 10% or less, preferably 8.0% or less, more preferably 6.5% or less, and still more preferably 5.0% or less. The lower limit thereof is often 1.5% or more. The above-described rate of change of K (absorption coefficient)/S (scattering coefficient) is a value obtained by comparing K (absorption coefficient)/S (scattering coefficient) at the specific maximal absorption wavelength before and after a heating treatment of the protective film at 140° C. for 30 minutes [100×(|K (absorption coefficient)/S (scattering coefficient) at specific maximal absorption wavelength before heating treatment|−|K (absorption coefficient)/S (scattering coefficient) at specific maximal absorption wavelength after heating treatment|)/K (absorption coefficient)/S (scattering coefficient) at specific maximal absorption wavelength before heating treatment].

In a case where the protective film has a plurality of specific maximal absorption wavelengths in the wavelength range of 300 to 400 nm, it is preferable that any specific maximal absorption wavelength has the above-described rate of change of K (absorption coefficient)/S (scattering coefficient) within the above-described range.

Examples of a method for measuring the above-described K (absorption coefficient)/S (scattering coefficient) include the following method.

First, a total of 30 mg of the protective film is scraped off, mixed with barium sulfate (270 mg), and crushed using an agate mortar so that a particle diameter of a solid powder is 2 m or less, thereby obtaining a sample for measurement. The sample for measurement (approximately 100 mg) is set on a specimen table, and flattened such that a gap is not generated in the measurement range. Next, using a measurement instrument V-7200 (manufactured by JASCO Corporation), diffuse reflectivities of the barium sulfate (standard sample) and the sample for measurement at a wavelength of 300 to 700 nm are measured to obtain a relative reflectivity R of the sample for measurement. Next, the relative reflectivity R (%) obtained by the measurement is converted into K (absorption coefficient)/S (scattering coefficient) based on the following expression.

$$K / S = {( 1 - R )}^{2} / 2 R$$

The above expression is called a Kubelka-Munk function.

By the above-described conversion, a graph of horizontal axis: wavelength and vertical axis: K (absorption coefficient)/S (scattering coefficient) is obtained, and a peak top in a wavelength range of 300 to 400 nm in the graph is defined as the specific maximal absorption wavelength. K (absorption coefficient)/S (scattering coefficient) at the specific maximal absorption wavelength is determined. The obtained K/S corresponds to K (absorption coefficient)/S (scattering coefficient) at the specific maximal absorption wavelength before a heating treatment.

Next, after heating the protective film at 140° C. for 30 minutes, the above-described K (absorption coefficient)/S (scattering coefficient) at the specific maximal absorption wavelength in a wavelength range of 300 to 400 nm is determined according to the same procedure as described above. The obtained K/S corresponds to K (absorption coefficient)/S (scattering coefficient) at the specific maximal absorption wavelength after the heating treatment.

### <K (Absorption Coefficient)/S (Scattering Coefficient)>

K (absorption coefficient)/S (scattering coefficient) at the specific maximal absorption wavelength after heating the protective film at 140° C. for 30 minutes is preferably 4.0 or less. The lower limit thereof is preferably 0.01 or more, more preferably 0.05 or more, and still more preferably 0.1 or more.

In a case where the protective film has a plurality of specific maximal absorption wavelengths in the wavelength range of 300 to 400 nm, it is preferable that any specific maximal absorption wavelength has the K (absorption coefficient)/S (scattering coefficient) within the above-described range.

### <Other Physical Properties>

As will be described later, since the protective film has a reduced content of the acid group, polarity is low and moisture permeability and relative permittivity are low. The content of the acid group in the protective film is reduced by preferably 5 mol % or more, more preferably 10 mol % or more, still more preferably 20 mol % or more, even more preferably 31 mol % or more, particularly preferably 40 mol % or more, more particularly preferably 51 mol % or more, and most preferably 71 mol % or more with respect to the content of the acid group in the photosensitive layer (for example, a photosensitive layer formed in a step X1 described later or a step Y1 described later). The upper limit thereof is, for example, less than 100 mol %.

The reduction rate of the content of the acid group can be calculated, for example, by measuring an amount of the acid group of the photosensitive layer before exposure and an amount of the acid group of the protective film after the exposure. In a case of measuring the amount of the acid group in the photosensitive layer before the exposure, for example, the amount thereof can be analyzed and quantified by potentiometric titration. In a case of measuring the amount of the acid group in the protective film after the exposure, the hydrogen atom of the acid group is substituted with a metal ion such as lithium, and the amount thereof can be calculated by analyzing and quantifying the amount of this metal ion by inductively coupled plasma optical emission spectrometer (ICP-OES).

In addition, the above-described reduction rate of the content of the acid group can also be calculated by measuring an infrared (IR) spectrum of the photosensitive layer before and after the exposure and measuring a reduction rate of a peak derived from the acid group.

A moisture permeability of the protective film is reduced by preferably 5% or more, more preferably 10% or more, and still more preferably 20% or more with respect to the moisture permeability of the photosensitive layer (for example, a photosensitive layer formed in a step X1 described later or a step Y1 described later). The upper limit thereof is, for example, less than 100%.

A relative permittivity of the protective film is reduced by preferably 5% or more, more preferably 10% or more, and still more preferably 15% or more with respect to the relative permittivity of the photosensitive layer (a photosensitive layer formed in a step X1 described later or a step Y1 described later). The upper limit thereof is, for example, less than 100%.

The protective film is preferably achromatic.

Specifically, in CIE1976 (L*a*b*) color space of the total reflection (incidence angle: 8°, light source: D-65 (visual field: 2°)), the L* is preferably 10 to 90, the a* is preferably −1.0 to 1.0, and the b* is preferably −1.0 to 1.0.

A thickness of the protective film is preferably 0.5 to 20 m, more preferably 0.8 to 15 m, and still more preferably 1.0 to 10 m.

### [Use of Protective Film]

As a use of the protective film, the protective film can be used as various protective films.

In addition, the protective film can also be used as various insulating films.

Specific examples thereof include the use as a protective film which protects a conductive pattern, the use as an interlayer insulating film between conductive patterns, and the use as an etching resist film in the manufacturing of the circuit wiring. From the viewpoint that low moisture permeability is excellent, the above-described pattern is preferably used as a protective film (permanent film) which protects the conductive pattern or as an interlayer insulating film between the conductive patterns.

The above-described protective film can be used as a protective film (permanent film) which protects a conductive pattern such as an electrode pattern corresponding to a sensor in a visual recognition portion and a wiring line for a peripheral wiring portion and a lead-out wiring portion is provided inside the touch panel, or as an interlayer insulating film between conductive patterns. In addition, the above-described protective film can be used as a protective film (permanent film) which protects a conductive pattern such as a display device, a printed wiring board, and a wiring line of a semiconductor package, or as an interlayer insulating film between conductive patterns.

### [Method for Manufacturing Protective Film]

Examples of a method for manufacturing the protective film include a known manufacturing method.

For example, the protective layer may be formed by applying a composition containing the above-described polymer A may be applied onto a base material.

In addition, the protective layer may be formed by a method accompanied by an exposure treatment.

Specific examples thereof include a method of forming a photosensitive layer on a base material using a photosensitive material described later, and exposing and developing the photosensitive layer, and a method in which, using a transfer film having a temporary support and a photosensitive layer formed of a photosensitive material, the photosensitive layer transferred onto any base material is exposed and developed through a mask having a predetermined pattern shape.

The above-described photosensitive material and the above-described transfer film are as described later.

It is preferable that the photosensitive material and the photosensitive layer contain a polymer P having the repeating unit A and the compound B, or contain a polymer P having the repeating unit A and the repeating unit B.

In a case of the above-described configurations, the photosensitive layer has a function of reducing the content of the acid group included in the polymer P by exposure. Hereinafter, estimation mechanism will be described in detail by taking the compound B as an example. In the following, the compound B may be read as the repeating unit B.

In a case where the above-described compound B is exposed, acceptability of electron increases, and the electron is transferred from the acid group included in the polymer P. In a case where the acid group transfers the electron to the compound B, the above-described acid group is unstable and to be carbon dioxide, and is eliminated. In a case where the acid group is to be carbon dioxide and is eliminated, polarity of that portion decreases. That is, in the photosensitive layer, by the above-described mechanism of action, the polarity changes due to the elimination of the acid group included in the polymer P in the exposed portion, and the solubility in a developer changes (in the exposed portion, the solubility in an alkali developer is decreased and the solubility in an organic solvent-based developer is increased). On the other hand, in the non-exposed portion, the solubility in the developer has not changed. As a result, the photosensitive layer can form a pattern.

In a case where the developer is an alkali developer, the content of the acid group included in the polymer P is reduced, and thus it is possible to form a pattern having an excellent relative permittivity. In a case where the developer is an organic solvent-based developer, by further performing an exposure treatment on the developed pattern, the content of the acid group included in the polymer P is reduced, and thus it is possible to form a pattern having an excellent relative permittivity.

In the above-described procedure, the content of the acid group included in the polymer P is reduced, the above-described polymer A, and as a result, a protective layer exhibiting a predetermined acid value is formed.

The photosensitive material also preferably contains a polymerizable compound. As described above, in a case where the above-described acid group transfers the electron to the compound B, the above-described acid group is unstable and to be carbon dioxide, and is eliminated. In this case, a radical is generated at a position where the acid group included in the polymer P is to be carbon dioxide and is eliminated, and the radical causes a radical polymerization reaction of the polymerizable compound. As a result, the photosensitive layer has more excellent pattern formability particularly to the alkali developer, and the formed pattern also has excellent film hardness.

The photosensitive material also preferably contains a polymerizable compound and a photopolymerization initiator.

In a case where the photosensitive material contains a photopolymerization initiator, the elimination reaction of the acid group included in the polymer P and the polymerization reaction can occur at different timings. For example, first, the photosensitive layer may be subjected to a first exposure with a wavelength or an exposure amount at which the elimination reaction of the acid group hardly occurs, and the polymerization reaction of the polymerizable compound based on the photopolymerization initiator may be allowed to proceed for curing. Thereafter, the cured photosensitive layer may be subjected to a second exposure to eliminate the acid group.

Examples of embodiments of the photosensitive material are shown below.

### Photosensitive Material of Embodiment X-1-a1

The photosensitive material and the photosensitive layer of the transfer film contain a polymer P having the repeating unit A and the compound B, or contain a polymer P having the repeating unit A and the repeating unit B, and the photosensitive material contains substantially no polymerizable compound and photopolymerization initiator.

### Photosensitive Material of Embodiment X-1-a2

The photosensitive material and the photosensitive layer of the transfer film contain a polymer P having the repeating unit A and the compound B, or contain a polymer P having the repeating unit A and the repeating unit B, and the photosensitive material contains substantially no photopolymerization initiator.

Photosensitive Material of Embodiment X-1-a3 The photosensitive material and the photosensitive layer of the transfer film contain a polymer P having the repeating unit A and the compound B, or contain a polymer P having the repeating unit A and the repeating unit B, and the photosensitive material contains a polymerizable compound and a photopolymerization initiator.

In the photosensitive material of the embodiment X-1-a1, the “photosensitive material contains substantially no polymerizable compound” means that a content of the polymerizable compound may be less than 3% by mass, preferably 0% to 1% by mass and more preferably 0% to 0.1% by mass with respect to the total solid content of the photosensitive material.

In the photosensitive materials of the embodiment X-1-a1 and the embodiment X-1-a2, the “photosensitive material contains substantially no photopolymerization initiator” means that a content of the photopolymerization initiator may be less than 0.1% by mass, preferably 0% to 0.05% by mass and more preferably 0% to 0.01% by mass with respect to the total solid content of the photosensitive material.

### [Photosensitive Material]

### [Polymer P]

The photosensitive material preferably contains a polymer P.

The polymer P has the above-described repeating unit A having an acid group.

The description of the repeating unit A having an acid group is as described above.

A content of the repeating unit having an acid group (preferably, the repeating unit having a carboxy group) in the polymer P is preferably 1 mol % or more and more preferably 5 mol % or more with respect to all repeating units of the polymer P. The upper limit thereof is often 100 mol % or less, preferably 65 mol % or less and more preferably 45 mol % or less with respect to all repeating units of the polymer P.

The content of the repeating unit having an acid group (preferably, the repeating unit having a carboxy group) in the polymer P is preferably 1% by mass or more and more preferably 5% by mass or more with respect to all repeating units of the polymer P. The upper limit thereof is often less than 100% by mass, preferably 70% by mass or less and more preferably 50% by mass or less with respect to all repeating units of the polymer P.

The polymer P may include the above-described repeating unit B.

A content of the repeating unit B is preferably 3 to 75 mol %, more preferably 5 to 60 mol %, and still more preferably 10 to 50 mol % with respect to all repeating units of the polymer P.

The content of the repeating unit B is preferably 1% to 75% by mass, more preferably 3% to 60% by mass, and still more preferably 5% to 30% by mass with respect to all repeating units of the polymer P.

The polymer P may include the above-described repeating unit having an aromatic ring.

A content of the repeating unit having an aromatic ring in the polymer P is preferably 5 to 80 mol %, more preferably 15 to 75 mol %, and still more preferably 30 to 70 mol % with respect to all repeating units of the polymer P.

The content of the repeating unit having an aromatic ring in the polymer P is preferably 5% to 90% by mass, more preferably 10% to 80% by mass, and still more preferably 30% to 70% by mass with respect to all repeating units of the polymer P.

The polymer P may include the above-described repeating unit having an alicyclic structure.

A content of the repeating unit having an alicyclic structure in the polymer P is preferably 3 to 70 mol %, more preferably 5 to 60 mol %, and still more preferably 10 to 55 mol % with respect to all repeating units of the polymer P.

The content of the repeating unit having an alicyclic structure in the polymer P is preferably 3% to 90% by mass, more preferably 5% to 70% by mass, and still more preferably 20% to 60% by mass with respect to all repeating units of the polymer P.

From the viewpoint of excellent formability of the photosensitive layer, a weight-average molecular weight of the polymer P is preferably 5,000 or more, more preferably 10,000 or more, and still more preferably 15,000 or more. From the viewpoint of more excellent adhesiveness (laminate adhesiveness) in a case of being bonded to any base material (during transfer), the upper limit thereof is preferably 50,000 or less.

The polymer P may include the above-described other repeating units.

A content of the other repeating units in the polymer P is preferably 1 to 70 mol %, more preferably 2 to 50 mol %, and still more preferably 3 to 20 mol % with respect to all repeating units of the polymer P.

The content of the other repeating units in the polymer P is preferably 1% to 70% by mass, more preferably 1% to 50% by mass, and still more preferably 1% to 35% by mass with respect to all repeating units of the polymer P.

### <Repeating Unit Having Polymerizable Group>

The polymer P may include a repeating unit having a polymerizable group.

Examples of the polymerizable group include an ethylenically unsaturated group (for example, a (meth)acryloyl group, a vinyl group, a styryl group, and the like), and a cyclic ether group (for example, an epoxy group, an oxetanyl group, and the like), and an ethylenically unsaturated group is preferable and a (meth)acryloyl group is more preferable.

Examples of the repeating unit having a polymerizable group include a repeating unit represented by Formula (B).

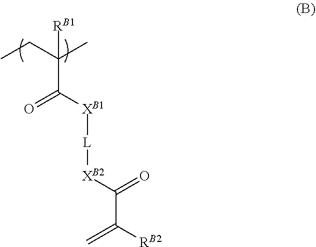

In Formula (B), X^{B1} and X^{B2} each independently represent —O— or —NR^{N}—, R^{N} represents a hydrogen atom or an alkyl group, L represents an alkylene group or an arylene group, and R^{B1} and R^{B2} each independently represent a hydrogen atom or an alkyl group.

X^{B1} and X^{B2} each independently represent —O— or —NR^{N}—. R^{N} represents a hydrogen atom or an alkyl group.

The above-described alkyl group may be linear or branched. The number of carbon atoms in the above-described alkyl group is preferably 1 to 5.

L represents an alkylene group or an arylene group.

The above-described alkylene group may be linear or branched. The number of carbon atoms in the above-described alkylene group is preferably 1 to 5.

The above-described arylene group may be monocyclic or polycyclic. The number of carbon atoms in the above-described arylene group is preferably 6 to 15.

The above-described alkylene group and the above-described arylene group may further have a substituent. A hydroxy group is preferable as the above-described substituent.

R^{B1} and R^{B2} each independently represent a hydrogen atom or an alkyl group.

The above-described alkyl group may be linear or branched. The number of carbon atoms in the above-described alkyl group is preferably 1 to 5 and more preferably 1.

A content of the repeating unit having a polymerizable group in the polymer P is preferably 3 to 60 mol %, more preferably 5 to 40 mol %, and still more preferably 10 to 30 mol % with respect to all repeating units of the polymer P.

The content of the repeating unit having a polymerizable group in the polymer P is preferably 1% to 70% by mass, more preferably 5% to 50% by mass, and still more preferably 12% to 45% by mass with respect to all repeating units of the polymer P.

### [Compound B]

The photosensitive material preferably contains a compound B.

The compound B is a compound having a function of reducing an amount of the acid group included in the polymer P by exposure. The function is as described above.

As the compound B, from the viewpoint that the moisture permeability of the protective film is further lowered, an aromatic compound is preferable.

The aromatic compound is a compound having one or more aromatic rings.

Only one aromatic ring may be present in the compound B, or a plurality of aromatic rings may be present therein.

The aromatic ring may be an overall structure constituting the entire compound B or a partial structure constituting a part of the compound B.

The above-described aromatic ring may be monocyclic or polycyclic, and is preferably polycyclic. For example, the polycyclic aromatic ring is an aromatic ring in which a plurality of (for example, 2 to 5, or the like) aromatic ring structures is fused, and at least one of the plurality of aromatic ring structures preferably has a heteroatom as a ring member atom.

The above-described aromatic ring may be a heteroaromatic ring, and a heteroaromatic ring having 1 or more (for example, 1 to 4, or the like) heteroatoms (for example, nitrogen atom, oxygen atom, sulfur atom, and the like) as a ring member atom is preferable; and a heteroaromatic ring having 1 or more (for example, 1 to 4, or the like) nitrogen atoms as a ring member atom is more preferable.

The number of ring member atoms in the above-described aromatic ring is preferably 5 to 15.

Examples of the above-described aromatic ring include monocyclic aromatic rings such as a pyridine ring, a pyrazine ring, a pyrimidine ring, and a triazine ring; aromatic rings in which two rings are fused, such as a quinoline ring, an isoquinoline ring, a quinoxaline ring, and a quinazoline ring; and aromatic rings in which three rings are fused, such as an acridine ring, a phenanthridine ring, a phenanthroline ring, and a phenazine ring.

The above-described aromatic ring may have 1 or more (for example, 1 to 5, or the like) substituents.

Examples of the above-described substituent include an alkyl group, an aryl group, a halogen atom, an acyl group, an alkoxycarbonyl group, an arylcarbonyl group, a carbamoyl group, a hydroxy group, a cyano group, an amino group, and a nitro group. In addition, in a case where the above-described aromatic ring has two or more substituents, a plurality of substituents may be bonded to each other to form a non-aromatic ring.

In addition, it is also preferable that the above-described aromatic ring is directly bonded to a carbonyl group to form an aromatic carbonyl group in the compound B. It is also preferable that a plurality of aromatic rings is bonded through a carbonyl group.

It is also preferable that the above-described aromatic ring is bonded to an imide group to form an aromatic imide group in the compound B. The imide group in the aromatic imide group may or may not form an imide ring together with the aromatic ring.

A plurality of aromatic rings (for example, 2 to 5 aromatic rings) may form the series of aromatic ring structures bonded with a structure selected from the group consisting of a single bond, a carbonyl group, and a multiple bond (for example, a vinylene group which may have a substituent, —C≡C—, —N═N—, and the like). In addition, it is preferable that one or more of aromatic rings constituting the series of aromatic ring structures are the above-described heteroaromatic rings.

From the viewpoint that the moisture permeability of the protective film is further lowered, the compound B is preferably a compound satisfying 1 or more (for example, 1 to 4, or the like) of the following requirements (1) to (4). It is preferable that the compound B satisfies the requirement (2), and it is preferable that the heteroatom of the heteroaromatic ring has a nitrogen atom. That is, a nitrogen-containing aromatic compound is preferable.
(1) the compound B has a polycyclic aromatic ring.
(2) the compound B has a heteroaromatic ring.
(3) the compound B has an aromatic carbonyl group.
(4) the compound B has an aromatic imide group.

Specific examples of the compound B include monocyclic aromatic compounds such as pyridine and a pyridine derivative, pyrazine and a pyrazine derivative, pyrimidine and a pyrimidine derivative, and triazine and a triazine derivative; compounds in which two rings are fused to form an aromatic ring, such as quinoline and a quinoline derivative, isoquinoline and an isoquinoline derivative, quinoxaline and a quinoxaline derivative, and quinazoline and a quinazoline derivative; and compounds in which three or more rings are fused to form an aromatic ring, such as acridine and an acridine derivative, phenanthridine and a phenanthridine derivative, phenanthroline and a phenanthroline derivative, and phenazine and a phenazine derivative.

The compound B is preferably one or more kinds selected from the group consisting of pyridine and a pyridine derivative, quinoline and a quinoline derivative, isoquinoline and an isoquinoline derivative, and acridine and an acridine derivative; more preferably one or more kinds selected from the group consisting of quinoline and a quinoline derivative, and isoquinoline and an isoquinoline derivative; and still more preferably one or more kinds selected from the group consisting of isoquinoline and an isoquinoline derivative.

These compounds and derivatives thereof may further have a substituent.

As the above-described substituent, an alkyl group, an aryl group, a halogen atom, an acyl group, an alkoxycarbonyl group, an arylcarbonyl group, a carbamoyl group, a hydroxy group, a cyano group, an amino group, or a nitro group is preferable; an alkyl group, an aryl group, a halogen atom, an acyl group, an alkoxycarbonyl group, an arylcarbonyl group, a carbamoyl group, a hydroxy group, a cyano group, or a nitro group is more preferable; an alkyl group, an aryl group, an acyl group, an alkoxycarbonyl group, an arylcarbonyl group, a carbamoyl group, a hydroxy group, a cyano group, or a nitro group is still more preferable; and an alkyl group (for example, a linear or branched alkyl group having 1 to 10 carbon atoms) is particularly preferable.

In addition, from the viewpoint that the moisture permeability of the protective film is further lowered, the compound B is preferably an aromatic compound having a substituent (compound having a substituent at a constituent atom of the aromatic ring included in the compound B), and more preferably a compound which satisfies 1 or more (for example, 1 to 4) of the above-described requirements (1) to (4) and further has a substituent.

As a position of the substituent, for example, in a case where the compound B is quinoline or a quinoline derivative, from the viewpoint that the moisture permeability of the protective film is further lowered, it is preferable to have the substituent at at least a 2-position or a 4-position on the quinoline ring. In addition, for example, in a case where the compound B is isoquinoline or an isoquinoline derivative, from the viewpoint that the moisture permeability of the protective film is further lowered, it is preferable to have the substituent at at least a 1-position on the isoquinoline ring. The substituent is preferably an alkyl group (for example, a linear or branched alkyl group having 1 to 10 carbon atoms).

The compound B is preferably a compound represented by any one of Formula (B1), . . . , or Formula (B4).

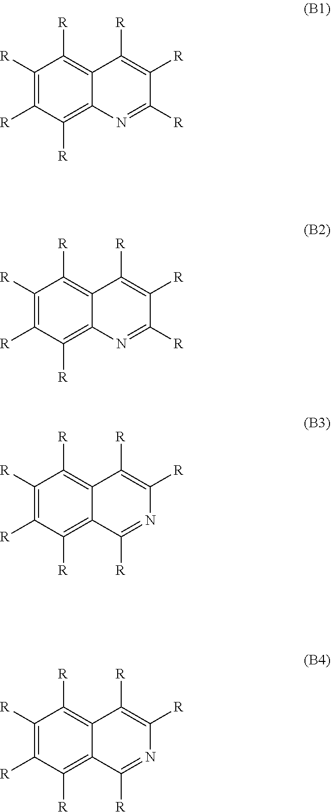

In Formulae (B1) to (B4), R's each independently represent a hydrogen atom or a substituent.

The above-described substituent is preferably an alkyl group.

The above-described alkyl group may be linear, branched, or cyclic.

The number of carbon atoms in the above-described alkyl group is preferably 1 to 5.

A plurality of R's may be the same or different from each other.

In Formula (B1), it is preferable that at least one of R's represents a hydrogen atom, it is more preferable that at least four of R's represent hydrogen atoms, and it is still more preferable that all R's represent hydrogen atoms.

In Formula (B2), it is preferable that at least one of R's represents a hydrogen atom, it is more preferable that at least four of R's represent hydrogen atoms, and it is still more preferable that all R's represent hydrogen atoms.

In Formula (B3), it is preferable that at least one of R's represents a hydrogen atom, it is more preferable that at least four of R's represent hydrogen atoms, and it is still more preferable that all R's represent hydrogen atoms.

In Formula (B4), it is preferable that at least one of R's represents a hydrogen atom, it is more preferable that at least four of R's represent hydrogen atoms, and it is still more preferable that all R's represent hydrogen atoms.

Examples of the compound B include 5,6,7,8-tetrahydroquinoline, 4-acetylpyridine, 4-benzoylpyridine, 1-phenylisoquinoline, 1-n-butylisoquinoline, 1-n-butyl-4-methylisoquinoline, 1-methylisoquinoline, 2,4,5,7-tetramethylquinoline, 2-methyl-4-methoxyquinoline, 2,4-dimethylquinoline, phenanthridine, 9-methylacridine, 9-phenylacridine, pyridine, isoquinoline, quinoline, acridine, 4-aminopyridine, and 2-chloropyridine.

The compound B preferably has the specific maximal absorption wavelength. That is, the compound B preferably has a maximal absorption wavelength in the wavelength range of 300 to 400 nm. In addition, the compound B may have another maximal absorption wavelength other than the specific maximal absorption wavelength.

The above-described specific maximal absorption wavelength is preferably in a wavelength range of 300 to 380 nm, more preferably in a wavelength range of 310 to 360 nm, and still more preferably in a wavelength range of 310 to 330 nm.

The compound B may have a plurality of specific maximal absorption wavelengths in the wavelength range of 300 to 400 nm.

Examples of a method for measuring the above-described specific maximal absorption wavelength include the method for measuring the specific maximal absorption wavelength of the protective film.

From the viewpoint that the moisture permeability of the protective film is further lowered, a molar absorption coefficient (ε₃₆₅) of the compound B to light having a wavelength of 365 nm is, for example, 20,000 (cm·mol/L)⁻¹ or less, preferably 18,000 (cm·mol/L)⁻¹ or less, more preferably less than 15,000 (cm·mol/L)⁻¹, and still more preferably 10,000 (cm- mol/L)⁻¹ or less. The lower limit of the above-described molar absorption coefficient F is, for example, more than 0 (cm·mol/L)⁻¹, preferably more than 1,000 (cm·mol/L)⁻¹.

In a case where ε₃₆₅ of the compound B is within the above-described range, it is suitable for an aspect in which the photosensitive layer is exposed through the temporary support (preferably, a PET film).

That is, in a case where the acid group included in the polymer P is a carboxy group, since the molar absorption coefficient ε₃₆₅ is moderately low, even in a case of being exposed through the temporary support, generation of bubbles due to the decarboxylation can be controlled, and deterioration of the pattern shape can be prevented.

In addition, by setting ε₃₆₅ of the compound B within the above-described range, coloration of the protective film can be suppressed.

As the compound B having such F₃₆₅, the above-described monocyclic aromatic compound or the above-described aromatic compound in which two rings are fused to form an aromatic ring is preferable; pyridine and a pyridine derivative, quinoline and a quinoline derivative, or isoquinoline and an isoquinoline derivative is more preferable; and isoquinoline or an isoquinoline derivative is still more preferable.

In addition, from the viewpoint that the moisture permeability of the protective film is further lowered, a molar absorption coefficient (ε₃₁₃) of the compound B to light having a wavelength of 313 nm is, for example, 20,000 (cm·mol/L)⁻¹ or less, preferably 18,000 (cm·mol/L)⁻¹ or less, more preferably less than 15,000 (cm·mol/L)⁻¹, and still more preferably 10,000 (cm·mol/L)⁻¹ or less. The lower limit of the above-described molar absorption coefficient ε is, for example, more than 0 (cm·mol/L)⁻¹, preferably more than 1,000 (cm·mol/L)⁻¹.

The ε₃₆₅ and ε₃₁₃ of the compound B are molar absorption coefficients measured by dissolving the compound B in acetonitrile. In a case where the compound B is insoluble in acetonitrile, a solvent for dissolving the compound B may be appropriately changed.

A lower limit of a pKa of the compound B in a ground state is preferably 0.50 or more, and from the viewpoint of more excellent pattern formability and/or viewpoint that the moisture permeability of the pattern to be formed is further lowered, it is more preferably 2.00 or more. In addition, an upper limit of the pKa of the compound B in a ground state is preferably 10.00 or less, more preferably 9.00 or less, still more preferably 8.00 or less, and particularly preferably 7.00 or less. The pKa of the compound B in a ground state is intended to be a pKa of the compound B in an unexcited state, and can be determined by acid titration. In a case where the compound B is a nitrogen-containing aromatic compound, the pKa of the compound B in a ground state is intended to be a pKa of a conjugate acid of the compound B.

A molecular weight of the compound B is preferably less than 5,000, more preferably less than 1,000, still more preferably 65 to 300, and particularly preferably 75 to 250.

In addition, in a case where the photosensitive layer is formed by coating, from the viewpoint of being less likely to volatilize in the coating process and having more excellent residual ratio in the photosensitive layer (from the viewpoint of more excellent pattern formability and/or viewpoint that the moisture permeability of the pattern to be formed is further lowered), the molecular weight of the compound B is more preferably 120 or more, more preferably 130 or more, and still more preferably 150 or more. The upper limit of the molecular weight of the compound B is preferably less than 5,000 and more preferably 1,000 or less.

In addition, in a case where the compound B is a compound exhibiting a cationic state (for example, a nitrogen-containing aromatic compound), an energy level of the highest occupied molecular orbital (HOMO) of the compound B in the cationic state is preferably −7.50 eV or less, and from the viewpoint of more excellent pattern formability and/or viewpoint that the moisture permeability of the pattern to be formed is further lowered, it is more preferably −7.80 eV or less. The lower limit thereof is preferably −13.60 eV or more.

In the present specification, the energy level of HOMO (HOMO in the first electron excited state) of the compound B in the cationic state is calculated by the quantum chemical calculation program Gaussian 09 (Gaussian 09, Revision A.02, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2009.).

As a calculation method, a time-dependent density functional theory using B3LYP as a functional and 6-31+G(d,p) as a basis function is used. In addition, in order to incorporate a solvent effect, a PCM method based on a chloroform parameter set in Gaussian 09 is also used in combination. By this method, a structure optimization calculation of the first electron excited state is performed to obtain a structure with the minimum energy, and the energy of HOMO in the structure is calculated.

Hereinafter, the HOMO energy level (eV) of a representative example of the compound B in a cationic state is shown. The molecular weight is also shown.

TABLE 1

| Compound β | Molecular | HOMO energy level in |
|---|---|---|
| (compound B) | weight | cationic state (eV) |
| Isoquinoline | 129 | −8.08 |
| Quinoline | 129 | −8.30 |
| Acridine | 179 | −7.70 |
| 2,4-Dimethylquinoline | 157 | −8.13 |
| 1-Me isoquinoline | 143 | −7.97 |
| Pyridine | 79 | −9.63 |

The compound B may be used alone or in combination of two or more kinds thereof.

A content of the compound B is preferably 0.1% to 50% by mass with respect to the total solid content of the photosensitive material.

In the photosensitive material of the embodiment X-1-a1, the content of the compound B is preferably 2% to 40% by mass, more preferably 4% to 35% by mass, and still more preferably 8% to 30% by mass with respect to the total solid content of the photosensitive material.

In the photosensitive material of the embodiment X-1-a2, the content of the compound B is preferably 0.5% to 20% by mass and more preferably 1% to 10% by mass with respect to the total solid content of the photosensitive material.

In the photosensitive material of the embodiment X-1-a3, the content of the compound B is preferably 0.3% to 20% by mass and more preferably 0.5% to 8% by mass with respect to the total solid content of the photosensitive material.

The total number of moles of the compound B is preferably 1 mol % or more, more preferably 3 mol % or more, still more preferably 5 mol % or more, particularly preferably 10 mol % or more, and most preferably 20 mol % or more with respect to the total number of moles of the acid group included in the polymer P. From the viewpoint of quality of the protective film to be obtained, the upper limit thereof is preferably 200 mol % or less, more preferably 100 mol % or less, and still more preferably 80 mol % or less with respect to the total number of moles of the acid group included in the polymer P.

### [Polymerizable Compound]

The photosensitive material may contain a polymerizable compound.

The above-described polymerizable compound is a component different from the polymer P and does not include an acid group.

The polymerizable compound is a polymerizable compound having 1 or more (for example, 1 to 15) ethylenically unsaturated groups in one molecule.

The polymerizable compound preferably includes a bi- or higher functional polymerizable compound.

Here, the bi- or higher functional polymerizable compound means a polymerizable compound having 2 or more (for example, 2 to 15) ethylenically unsaturated groups in one molecule.

Examples of the ethylenically unsaturated group include a (meth)acryloyl group, a vinyl group, and a styryl group, and a (meth)acryloyl group is preferable.

The polymerizable compound is also preferably (meth)acrylate.

The photosensitive material preferably contains a bifunctional polymerizable compound (preferably, bifunctional (meth)acrylate) and a tri- or higher functional polymerizable compound (preferably, tri- or higher functional (meth)acrylate).

Examples the bifunctional polymerizable compound include tricyclodecane dimethanol di(meth)acrylate, 1,9-nonanediol di(meth)acrylate, and 1,6-hexanediol di(meth)acrylate. Examples of the bifunctional polymerizable compound include tricyclodecane dimethanol diacrylate (A-DCP manufactured by Shin-Nakamura Chemical Co., Ltd.), tricyclodecane dimethanol dimethacrylate (DCP manufactured by Shin-Nakamura Chemical Co., Ltd.), 1,9-nonanediol diacrylate (A-NOD-N manufactured by Shin-Nakamura Chemical Co., Ltd.), and 1,6-hexanediol diacrylate (A-HD-N manufactured by Shin-Nakamura Chemical Co., Ltd.).

Examples of the tri- or higher functional polymerizable compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

The “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the polymerizable compound include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (A-GLY-9E manufactured by Shin-Nakamura Chemical Co., Ltd., or the like).

Examples of the polymerizable compound include urethane (meth)acrylate (preferably, tri- or higher functional urethane (meth)acrylate). The lower limit of the number of functional groups is preferably 6 or more and more preferably 8 or more. The upper limit of the number of functional groups is preferably 20 or less.

Examples of the tri- or higher functional urethane (meth)acrylate include 8UX-015A (manufactured by Taisei Fine Chemical Co., Ltd.); UA-32P, U-15HA, and UA-1100H (all manufactured by Shin-Nakamura Chemical Co., Ltd.); AH-600 manufactured by KYOEISHA CHEMICAL Co., LTD.; and UA-306H, UA-306T, UA-306I, UA-510H, and UX-5000 (all manufactured by Nippon Kayaku Co., Ltd.).

A molecular weight (in a case of having a molecular weight distribution, a weight-average molecular weight) of the polymerizable compound is preferably less than 5,000, more preferably 200 to 3,000, still more preferably 250 to 2,600, and particularly preferably 280 to 2,200.

Among molecular weights of all polymerizable compounds contained in the photosensitive material, the minimum molecular weight is preferably 250 or more and more preferably 280 or more.

The polymerizable compound may be used alone or in combination of two or more kinds thereof.

In a case of containing a polymerizable compound, a content of the polymerizable compound is preferably 3% to 70% by mass, more preferably 10% to 70% by mass, and still more preferably 20% to 55% by mass with respect to the total solid content of the photosensitive material.

A mass ratio of the content of the polymerizable compound to the content of the polymer P (content of polymerizable compound/content of polymer P) is preferably 0.2 to 2.0 and more preferably 0.4 to 0.9.

A content of the bifunctional polymerizable compound is preferably 10% to 90% by mass, more preferably 20% to 85% by mass, and still more preferably 30% to 80% by mass with respect to the total mass of all polymerizable compounds contained in the photosensitive material.

In addition, a content of the tri- or higher functional polymerizable compound is preferably 10% to 90% by mass, more preferably 15% to 80% by mass, and still more preferably 20% to 70% by mass with respect to the total mass of all polymerizable compounds contained in the photosensitive material.

In addition, the photosensitive material may contain the bi- or higher functional polymerizable compound and a monofunctional polymerizable compound.

It is preferable the bi- or higher functional polymerizable compound is a main component in the polymerizable compounds contained in the photosensitive material. Specifically, a content of the bi- or higher functional polymerizable compound is preferably 60% to 100% by mass, more preferably 80% to 100% by mass, and still more preferably 90% to 100% by mass with respect to the total mass of all polymerizable compounds contained in the photosensitive material.

### [Photopolymerization Initiator]

The photosensitive material may contain a photopolymerization initiator.

The photopolymerization initiator may be a photoradical polymerization initiator, a photocationic polymerization initiator, or a photoanionic polymerization initiator, but a photoradical polymerization initiator is preferable.

The photopolymerization initiator is preferably at least one selected from the group consisting of an oxime ester compound (photopolymerization initiator having an oxime ester structure) and an aminoacetophenone compound (photopolymerization initiator having an aminoacetophenone structure), and more preferably includes both compounds. In a case where both compounds are contained, a content of the oxime ester compound is preferably 5% to 90% by mass, and more preferably 15% to 50% by mass with respect to the total content of the both compounds.

In addition to the above-described photopolymerization initiators, other photopolymerization initiators may be included.

Examples of other photopolymerization initiators include a hydroxyacetophenone compound, an acylphosphine oxide compound, and a bistriphenylimidazole compound.

In addition, examples the photopolymerization initiator also include polymerization initiators described in paragraphs 0031 to 0042 of JP2011-095716A and paragraphs 0064 to 0081 of JP2015-014783A.

Examples of the oxime ester compound include 1,2-octanedione, 1-[4-(phenylthio)phenyl-,2-(O-benzoyloxime)] (product name: IRGACURE OXE-01; IRGACURE series, manufactured by BASF SE), etanone,1-[9-ethyl-6-(2-methylbenzoyl)-9H-carbazol-3-yl]-,1-(O-acetyloxime) (product name: IRGACURE OXE-02, manufactured by BASF SE), [5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) (product name: IRGACURE OXE-03, manufactured by BASF SE), 1-[4-[4-(2-benzofuranylcarbonyl)phenyl]thio]phenyl]-4-methylpentanone-1-(0-acetyloxime) (product name: IRGACURE OXE-04, manufactured by BASF SE, and product name: Lunar 6, manufactured by DKSH Management Ltd.), 1-[4-(phenylthio)phenyl]-3-cyclopentylpropan-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by Changzhou Tronly New Electronic Materials Co., Ltd.).

Examples of the aminoacetophenone compound include 2-(dimethylamino)-2-[(4-methylphenyl)methyl]-1-[4-(4-morpholinyl)phenyl]-1-butanone (product name: Omnirad 379EG; Omnirad series are manufactured by IGM Resins B.V.), 2-methyl-1-(4-methylthiophenyl)-2-morpholinopropan-1-one (product name: Omnirad 907), and APi-307 (1-(biphenyl-4-yl)-2-methyl-2-morpholinopropan-1-one, manufactured by Shenzhen UV-ChemTech Co., Ltd.).

Examples of the other photopolymerization initiators include 2-hydroxy-1-{4-[4-(2-hydroxy-2-methyl-propionyl)-benzyl]phenyl}-2-methyl-propan-1-one (product name: Omnirad 127), 2-benzyl-2-dimethylamino-1-(4-morpholinophenyl)-butanone-1 (product name: Omnirad 369), 2-hydroxy-2-methyl-1-phenyl-propan-1-one (product name: Omnirad 1173), 1-hydroxy-cyclohexyl-phenyl-ketone (product name: Omnirad 184), 2,2-dimethoxy-1,2-diphenylethane-1-one (product name: Omnirad 651), 2,4,6-trimethylbenzoyl-diphenylphosphine oxide (product name: Omnirad TPO H), and bis(2,4,6-trimethylbenzoyl) phenylphosphine oxide (product name: Omnirad 819).

The photopolymerization initiator may be used alone or in combination of two or more kinds thereof.

In a case of containing a photopolymerization initiator, a content of the photopolymerization initiator is preferably 0.1% to 15% by mass, more preferably 0.5% to 10% by mass, and still more preferably 1% to 5% by mass with respect to the total solid content of the photosensitive material.

### [Surfactant]

The photosensitive material may contain a surfactant.

Examples of the surfactant include an anionic surfactant, a cationic surfactant, a nonionic surfactant, and an amphoteric surfactant, and a nonionic surfactant is preferable.

Examples of the nonionic surfactant include polyoxyethylene higher alkyl ethers, polyoxyethylene higher alkylphenyl ethers, polyoxyethylene glycol higher fatty acid diesters, silicone-based surfactants, and fluorine-based surfactants.

As the surfactant, for example, surfactants described in paragraphs 0120 to 0125 of WO2018/179640A can also be used.

In addition, as the surfactant, surfactants described in paragraph 0017 of JP4502784B and surfactants described in paragraphs 0060 to 0071 of JP2009-237362A can also be used. Examples of a commercially available product of the fluorine-based surfactant include: MEGAFACE F-171, F-172, F-173, F-176, F-177, F-141, F-142, F-143, F-144, F-437, F-475, F-477, F-479, F-482, F-551, F-551-A, F-552, F-554, F-555-A, F-556, F-557, F-558, F-559, F-560, F-561, F-565, F-563, F-568, F-575, F-780, EXP.MFS-330, EXP.MFS-578, EXP.MFS-579, EXP.MFS-586, EXP.MFS-587, EXP.MFS-628, EXP.MFS-631, EXP.MFS-603, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED); and U-120E (manufactured by Uni-chem Co., Ltd.).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound is also preferably used.

In addition, as the fluorine-based surfactant, a block polymer can also be used. In addition, as the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactant, a fluorine-containing polymer having an ethylenically unsaturated bond-containing group in the side chain can also be used. Examples thereof include MEGAFACE RS-101, RS-102, RS-718K, and RS-72-K (all manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters; PLURONIC L10, L31, L61, L62, 1OR5, 17R2, and 25R2 (all of which are manufactured by BASF SE); TETRONIC 304, 701, 704, 901, 904, and 150R1 (all of which are manufactured by BASF SE); SOLSPERSE 20000 (all of which are manufactured by Lubrizol Corporation); NCW-101, NCW-1001, and NCW-1002 (all of which are manufactured by FUJIFILM Wako Pure Chemical Corporation); PIONIN D-6112, D-6112-W, and D-6315 (all of which are manufactured by Takemoto Oil&Fat Co., Ltd.); and OLFINE E1010 and SURFYNOL 104, 400, and 440 (all of which are manufactured by Nissin Chemical Co., Ltd.).

Examples of the silicone-based surfactant include a linear polymer consisting of a siloxane bond and a modified siloxane polymer with an organic group introduced in the side chain or the terminal.

Examples of the surfactant include EXP.S-309-2, EXP.S-315, EXP.S-503-2, and EXP.S-505-2 (all of which are manufactured by DIC Corporation); DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.); X-22-4952, X-22-4272, X-22-6266, KF-351A, K354L, KF-355A, KF-945, KF-640, KF-642, KF-643, X-22-6191, X-22-4515, KF-6004, KP-341, KF-6001, KF-6002, KP-101, KP-103, KP-104, KP-105, KP-106, KP-109, KP-112, KP-120, KP-121, KP-124, KP-125, KP-301, KP-306, KP-310, KP-322, KP-323, KP-327, KP-368, KP-369, KP-611, KP-620, KP-621, KP-626, and KP-652 (all of which are manufactured by Shin-Etsu Silicone Co., Ltd.); F-4440, TSF-4300, TSF-4445, TSF-4460, and TSF-4452 (all of which are manufactured by Momentive Performance Materials Co., Ltd.); and BYK300, BYK306, BYK307, BYK310, BYK320, BYK323, BYK325, BYK330, BYK313, BYK315N, BYK331, BYK333, BYK345, BYK347, BYK348, BYK349, BYK370, BYK377, and BYK378 (all of which are manufactured by BYK Chemie).

The surfactant may be used alone or in combination of two or more kinds thereof. A content of the surfactant is preferably 0.0001% to 10% by mass, more preferably 0.001% to 5% by mass, and still more preferably 0.005% to 3% by mass with respect to the total solid content of the photosensitive material.

### <Solvent>

The photosensitive material may contain a solvent.

As the solvent, an organic solvent is preferable.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, 2-propanol, and a mixed solvent thereof.

As the solvent, a mixed solvent of methyl ethyl ketone and propylene glycol monomethyl ether acetate, a mixed solvent of diethylene glycol ethyl methyl ether and propylene glycol monomethyl ether acetate, or a mixed solvent of methyl ethyl ketone, propylene glycol monomethyl ether, and propylene glycol monomethyl ether acetate is preferable.

The solvent may be used alone or in combination of two or more kinds thereof. In a case where the photosensitive material contains a solvent, the solid content of the photosensitive material is preferably 5% to 80% by mass, more preferably 8% to 40% by mass, and still more preferably 10% to 30% by mass. That is, in a case where the photosensitive material contains a solvent, a content of the solvent is preferably 20% to 95% by mass, more preferably 60% to 95% by mass, and still more preferably 70% to 95% by mass with respect to the total mass of the photosensitive material.

In a case where the photosensitive material contains a solvent, from the viewpoint of coating properties, a viscosity (25° C.) of the photosensitive material is preferably 1 to 50 mPa·s, more preferably 2 to 40 mPa·s, and still more preferably 3 to 30 mPa·s.

The above-described viscosity can be measured by using, for example, VISCOMETER TV-22 (manufactured by TOKI SANGYO CO. LTD.).

In a case where the photosensitive material contains a solvent, from the viewpoint of coating properties, a surface tension (25° C.) of the photosensitive material is preferably 5 to 100 mN/m, more preferably 10 to 80 mN/m, and still more preferably 15 to 40 mN/m. The above-described surface tension can be measured using, for example, Automatic Surface Tensiometer CBVP-Z (manufactured by Kyowa Interface Science Co., Ltd.).

Examples of the solvent also include Solvent described in paragraphs 0054 and 0055 of US2005/282073A, the contents of which are incorporated in the present specification.

In addition, examples of the solvent also include an organic solvent (high-boiling-point solvent) having a boiling point of 180° C. to 250° C.

### [Other Additives]

The photosensitive material may contain other additives.

Examples the other additives include a plasticizer, a sensitizer, a heterocyclic compound, and an alkoxysilane compound.

Examples of the plasticizer, the sensitizer, the heterocyclic compound, and the alkoxysilane compound include those described in paragraphs 0097 to 0119 of WO2018/179640A.

In addition, the photosensitive material may further contain, as other additives, a known additive such as a rust inhibitor, metal oxide particles, an antioxidant, a dispersing agent, an acid proliferation agent, a development promoter, a conductive fiber, a colorant, a thermal radical polymerization initiator, a thermal acid generator, an ultraviolet absorber, a thickener, a crosslinking agent, and an organic or inorganic anti-precipitation agent.

Suitable aspects of these components are described in paragraphs 0165 to 0184 of JP2014-085643A, the contents of which are incorporated in the present specification.

The other additives may be used alone or in combination of two or more kinds thereof.

The photosensitive material may contain impurities.

Examples of the impurities include sodium, potassium, magnesium, calcium, iron, manganese, copper, aluminum, titanium, chromium, cobalt, nickel, zinc, tin, halogen, and ions of these. Halide ion, sodium ion, and potassium ion are easily mixed as the impurities, so that the following content is preferable.

A content of the impurities in the photosensitive material is preferably 80 ppm by mass or less, more preferably 10 ppm by mass or less, and still more preferably 2 ppm by mass or less with respect to the total solid content of the photosensitive material. The lower limit thereof is preferably 1 ppb by mass or more, and more preferably 0.1 ppm by mass or more with respect to the total solid content of the photosensitive material.

Examples of a method of setting the impurities in the above-described range include selecting a raw material having a low content of impurities as a raw material for the photosensitive material, preventing the impurities from being mixed in a case of forming the photosensitive material, and washing and removing the impurities. By such a method, the amount of impurities can be kept within the above-described range.

Examples of a method of measuring the content of the impurities include a known method such as a method inductively coupled plasma (ICP) emission spectroscopy, atomic absorption spectroscopy, and ion chromatography.

### [Transfer Film]

As described above, the transfer film can be used for forming the protective layer.

The transfer film preferably includes a temporary support and a photosensitive layer.

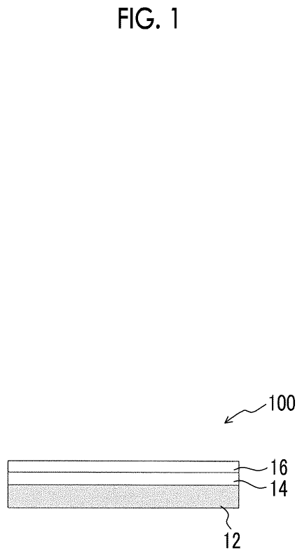

FIG. 1 is a schematic cross-sectional view showing an example of an embodiment of the transfer film according to the present invention.

A transfer film 100 shown in FIG. 1 has a configuration in which a temporary support 12, a photosensitive layer 14, and a cover film 16 are laminated in this order.

The transfer film 100 shown in FIG. 1 is in a form in which the cover film 16 is disposed, but the cover film 16 may not be disposed.

### [Temporary Support]

The temporary support is a support which supports the photosensitive layer and can be peeled off from the photosensitive layer.

From the viewpoint that the photosensitive layer can be exposed through the temporary support in a case where the photosensitive layer is exposed in a patterned manner, the temporary support preferably has light-transmitting property.

Here, the “having light-transmitting property” means that a transmittance of light having a main wavelength used for exposure (may be pattern exposure or entire exposure) is 50% or more. From the viewpoint of more excellent exposure sensitivity, the transmittance of the light having the main wavelength used for the exposure is preferably 60% or more, and more preferably 70% or more. Examples of a method of measuring the transmittance include a measuring method using MCPD Series manufactured by OTSUKA ELECTRONICS Co., Ltd.

Specifically, as the transmittance of the temporary support, any of transmittances at a wavelength of 313 nm, at a wavelength of 365 nm, at a wavelength of 405 nm, and at a wavelength of 436 nm is preferably 70% or more, more preferably 80% or more, and still more preferably 90% or more. Examples of a preferred value of the transmittance at each of the above-described wavelengths include 87%, 92%, and 98%.

Specific examples of the temporary support include a glass substrate, a resin film, and paper, and from the viewpoint of more excellent strength and flexibility, a resin film is preferable. Examples of the resin film include a polyethylene terephthalate film, a cellulose triacetate film, a polystyrene film, and a polycarbonate film. A biaxially stretched polyethylene terephthalate film is preferable.

From the viewpoint of pattern formability during the pattern exposure through the temporary support and transparency of the temporary support, it is preferable that the number of particles, foreign substances, and defects included in the temporary support is small. The number of fine particles, foreign substances, and defects having a diameter of 2 m or more is preferably 50 pieces/10 mm² or less, more preferably 10 pieces/10 mm² or less, and still more preferably 3 pieces/10 mm² or less. The lower limit thereof is not particularly limited, but can be 1 piece/10 mm² or more.

From the viewpoint of further improving handleability, the temporary support preferably has a layer in which 1 pieces/mm² or more particles with a diameter of 0.5 to 5 m are present on a surface opposite to the side where the photosensitive layer is formed, and more preferably has a layer in which 1 to 50 pieces/mm² particles with a diameter of 0.5 to 5 m are present.

From the viewpoint of ease of handling and excellent general-purpose properties, a thickness of the temporary support is preferably 5 to 200 m and more preferably 10 to 150 m.

From the viewpoint of strength as a support, flexibility required for bonding to a substrate for forming a circuit wiring, and light-transmitting property required in a first exposing step, the thickness of the temporary support can be appropriately selected according to a material.

The temporary support may be a recycled product. Examples of the recycled product include films obtained by washing used films and the like, making the used films and the like into chips, and using the chips as a material. Examples of the temporary support as the recycled product include Ecouse series manufactured by Toray Industries, Inc.

Examples of the temporary support include descriptions in paragraphs 0017 and 0018 of JP2014-085643A, paragraphs 0019 to 0026 of JP2016-027363A, paragraphs 0041 to 0057 of WO2012/081680A1, and paragraphs 0029 to 0040 of WO2018/179370A1, the contents of which are incorporated in the present specification.

Examples of the temporary support also include COSMOSHINE (registered trademark) A4100, COSMOSHINE (registered trademark) A4160, and COSMOSHINE (registered trademark) A4360 manufactured by Toyobo Co., Ltd.; LUMIRROR (registered trademark) 16FB40 manufactured by Toray Industries, Inc.; and LUMIRROR (registered trademark) 16KS40 (16QS62), LUMIRROR (registered trademark) #38-U48, LUMIRROR (registered trademark) #75-U34, and LUMIRROR (registered trademark) #25-T60 manufactured by Toray Industries, Inc.

In addition, as the temporary support, a biaxial stretching polyethylene terephthalate film having a thickness of 16 m, a biaxial stretching polyethylene terephthalate film having a thickness of 12 m, or a biaxial stretching polyethylene terephthalate film having a thickness of 9 m is preferable.

### [Photosensitive Layer]

Various components which can be contained in the photosensitive layer are the same as the various components which can be contained in the above-described photosensitive material, and suitable ranges thereof are also the same.

Suitable numerical ranges of the contents of the various components in the photosensitive layer are the same as suitable ranges in which “content (% by mass) of various components with respect to the total solid content of the photosensitive material” described above is read as “content (% by mass) of various components with respect to the total mass of the photosensitive layer”. Specifically, the description of “content of the polymer P in the photosensitive material is preferably 25% to 100% by mass with respect to the total solid content of the photosensitive material” is read as “content of the polymer P in the photosensitive layer is preferably 25% to 100% by mass with respect to the total mass of the photosensitive layer”. As described above, the solid content means all the components of the photosensitive material excluding the solvent. In addition, in a case where the photosensitive material is liquid, components other than the solvent are regarded as the solid content.

In a case where the photosensitive layer is formed of a photosensitive material including a solvent, the solvent may remain, but it is preferable that the photosensitive layer does not include the solvent.

A content of the solvent in the photosensitive layer is preferably 5% by mass or less, more preferably 2% by mass or less, still more preferably 1% by mass or less, particularly preferably 0.5% by mass or less, and most preferably 0.1% by mass or less with respect to the total mass of the photosensitive layer. The lower limit thereof is often 0% by mass or more with respect to the total mass of the photosensitive layer.

In addition, in the photosensitive layer, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low. A content of these compounds in the photosensitive layer is preferably 100 ppm by mass or less, more preferably 20 ppm by mass or less, and still more preferably 4 ppm by mass or less with respect to the total mass of the photosensitive layer. The lower limit thereof may be 10 ppb by mass or more or 100 ppb by mass or more with respect to the total mass of the photosensitive layer.

Examples of a method for measuring these compounds include a known measuring method.

From the viewpoint of more excellent pattern formability, a content of water in the photosensitive layer is preferably 0.01% to 1.0% by mass and more preferably 0.05% to 0.5% by mass with respect to the total mass of the photosensitive layer.

### [Physical Properties of Photosensitive Layer]

An average thickness of the photosensitive layer is preferably 0.5 to 20 μm.

In a case where the average thickness of the photosensitive layer is 20 m or less, resolution of the pattern is more excellent, and in a case where the average thickness of the photosensitive layer is 0.5 μm or more, it is preferable from the viewpoint of pattern linearity. The average thickness of the photosensitive layer is more preferably 0.8 to 15 μm and still more preferably 1.0 to 10 μm. Specific examples of the average thickness of the photosensitive layer include 3.0 μm, 5.0 μm, and 8.0 μm.

From the viewpoint of more excellent pattern formability and/or viewpoint that the moisture permeability of the pattern to be formed is further lowered, a transmittance of the photosensitive layer to light having a wavelength of 365 nm is preferably 20% or more, more preferably 65% or more, and still more preferably 90% or more. The upper limit thereof is, for example, 100% or less.

In addition, from the viewpoint of more excellent pattern formability and/or viewpoint that the moisture permeability of the pattern to be formed is further lowered, a ratio of the transmittance of the photosensitive layer to light having a wavelength of 365 nm to a transmittance of the photosensitive layer light having a wavelength of 313 nm (transmittance of photosensitive layer to light having wavelength of 365 nm/transmittance of photosensitive layer to light having wavelength of 313 nm) is preferably 1 or more and more preferably 1.5 or more. The upper limit thereof is, for example, 1,000 or less.

A visible light transmittance of the photosensitive layer at a thickness of approximately 1.0 m is preferably 80% or more, more preferably 90% or more, and still more preferably 95% or more.

As the visible light transmittance, it is preferable that an average transmittance to light having a wavelength of 400 to 800 nm, the minimum value of a transmittance to light having a wavelength of 400 to 800 nm, and a transmittance to light having a wavelength of 400 nm all satisfy the above. Specific examples of the visible light transmittance of the photosensitive layer at a thickness of approximately 1.0 m include 87%, 92%, and 98%.

From the viewpoint of suppressing residue during development, a dissolution rate of the photosensitive layer in a 1.0% by mass aqueous solution of sodium carbonate is preferably 0.01 m/sec or more, more preferably 0.10 μm/sec or more, and still more preferably 0.20 μm/sec or more. From the viewpoint of edge shape of the pattern, the upper limit thereof is preferably 5.0 m/sec or less. Specific examples of the above-described dissolution rate include 1.8 μm/sec, 1.0 μm/sec, and 0.7 μm/sec.

The dissolution rate of the photosensitive layer in a 1.0% by mass sodium carbonate aqueous solution per unit time can be measured by the following measuring method. A photosensitive layer (within a film thickness range of 1.0 to 10 μm) formed on a glass substrate, from which a solvent has been sufficiently removed, is subjected to a shower development with a 1.0% by mass sodium carbonate aqueous solution at 25° C. until the photosensitive layer is dissolved completely. The above-described development is performed for a maximum of 2 minutes. Next, the dissolution rate is obtained by dividing the thickness of the photosensitive layer by the time required for the photosensitive layer to be completely dissolved. In a case where the photosensitive layer is not dissolved completely in 2 minutes of development, the dissolution rate is calculated in the same manner as above from the amount of change in the photosensitive layer so far.

For the development, a shower nozzle of ¼ MINJJX030PP manufactured by H.IKEUCHI Co., Ltd. is used, and a spraying pressure of the shower is set to 0.08 MPa. Under the above-described conditions, a shower flow rate per unit time is set to 1,800 mL/min.

From the viewpoint of pattern formability, the number of foreign substances having a diameter of 1.0 m or more in the photosensitive layer is preferably 10 pieces/mm² or less, and more preferably 5 pieces/mm² or less.

The number of foreign substances can be measured by the following measuring method.

Any five regions (1 mm×1 mm) on a surface of the photosensitive layer are visually observed from a normal direction of the surface of the photosensitive layer with an optical microscope, the number of foreign substances having a diameter of 1.0 m or more in each region is measured, and the values are arithmetically averaged to calculate the number of foreign substances. Specific examples thereof include 0 pieces/mm², 1 piece/mm², 4 pieces/mm², and 8 pieces/mm².

From the viewpoint of suppressing generation of aggregates during the development, a haze of a solution obtained by dissolving 1.0 cm³ of the photosensitive layer in 1.0 L of a 1.0% by mass sodium carbonate aqueous solution at 30° C. is preferably 60% or less, more preferably 30% or less, still more preferably 10% or less, and particularly preferably 1% or less. The lower limit thereof is, for example, 0%.

The haze can be measured by the following measuring method.

First, a 1.0% by mass sodium carbonate aqueous solution is prepared, and a liquid temperature is adjusted to 30° C. 1.0 cm³ of the photosensitive layer is added to 1.0 L of the sodium carbonate aqueous solution. The solution is stirred at 30° C. for 4 hours, being careful not to mix air bubbles. After stirring, the haze of the solution in which the photosensitive layer is dissolved is measured. The haze is measured using a haze meter (product name “NDH4000”, manufactured by Nippon Denshoku Industries Co., Ltd.), a liquid measuring unit, and a liquid measuring cell having an optical path length of 20 mm. Specific examples of the haze include 0.4%, 1.0%, 9%, and 24%.

### [Other Layers]

The transfer film may include other layers, in addition to those described above.

Examples of other layers include a cover film, a layer of high refractive index, and other layers (for example, an interlayer and a thermoplastic resin layer).

In addition, in a case where a layer of high refractive index is formed on the temporary support or the cover film, the photosensitive layer may be formed on the layer of high refractive index.

### <Cover Film>

The transfer film may further include a cover film on a side of the photosensitive layer opposite to the temporary support.

In a case where the transfer film includes a layer of high refractive index, which will be described later, the cover film is preferably disposed on a side opposite to the temporary support (that is, a side opposite to the photosensitive layer) in a case of being viewed from the layer of high refractive index. In this case, for example, the transfer film is a laminate in which “temporary support/photosensitive layer/layer of high refractive index/cover film” are laminated in this order.

The cover film preferably has 5 pieces/m² or less of the number of fisheyes with a diameter of 80 m or more. The “fisheye” means that, in a case where a material is hot-melted, kneaded, extruded, biaxially stretched, cast and/or the like to produce a film, foreign substances, undissolved substances, oxidatively deteriorated substances, and/or the like of the material are incorporated into the cover film.

The number of particles having a diameter of 3 m or more in the cover film is preferably 30 particles/mm² or less, more preferably 10 particles/mm² or less, and still more preferably 5 particles/mm² or less. In the above, it is possible to suppress defects caused by ruggedness due to the particles in the cover film being transferred to the photosensitive layer.

An arithmetic average roughness Ra of a surface of the cover film is preferably 0.01 m or more, more preferably 0.02 m or more, and still more preferably 0.03 m or more. In a case of being within the above-described range, take-up property in a case of winding the transfer film can be improved. From the viewpoint of suppressing defects during transfer, the upper limit thereof is preferably less than 0.50 m, more preferably 0.40 m or less, and still more preferably 0.30 m or less.

Examples of the cover film include a polyethylene terephthalate film, a polypropylene film, a polystyrene film, and a polycarbonate film.

As the cover film, for example, films described in paragraphs 0083 to 0087 and 0093 of JP2006-259138A may be used.

Examples of the cover film include ALPHAN (registered trademark) FG-201 manufactured by Oji F-Tex Co., Ltd., ALPHAN (registered trademark) E-201F manufactured by Oji F-Tex Co., Ltd., Cerapeel (registered trademark) 25WZ manufactured by TORAY ADVANCED FILM CO., LTD., and LUMIRROR (registered trademark) 16QS62 (16KS40) manufactured by Toray Industries, Inc.

The cover film may be a recycled product. Examples of the recycled product include films obtained by washing used films and the like, making the used films and the like into chips, and using the chips as a material. Examples of the recycled product include Ecouse (registered trademark) series manufactured by Toray Industries, Inc.

### <Layer of High Refractive Index>

The layer of high refractive index is preferably disposed adjacent to the photosensitive layer, and is also preferably disposed on a side opposite to the temporary support in a case of being viewed from the photosensitive layer.

The layer of high refractive index is a layer having a refractive index of 1.50 or more with respect to light having a wavelength of 550 nm.

The above-described refractive index of the layer of high refractive index is preferably 1.55 or more and more preferably 1.60 or more. The upper limit thereof is preferably 2.10 or less, more preferably 1.85 or less, still more preferably 1.78 or less, and particularly preferably 1.74 or less. In addition, it is preferable that the refractive index of the layer of high refractive index is higher than the refractive index of the photosensitive layer.

The layer of high refractive index may be photosensitive or thermosetting.

The aspect in which the layer of high refractive index has photosensitivity, has an advantage, from a viewpoint of collectively patterning the photosensitive layer and the layer of high refractive index transferred onto the base material by photolithography at one time, after the transferring.

The layer of high refractive index preferably has alkali solubility (for example, solubility with respect to weak alkali aqueous solution). In addition, the layer of high refractive index is preferably a transparent layer.

A thickness of the layer of high refractive index is preferably 500 nm or less, more preferably 110 nm or less, and still more preferably 100 nm or less. The lower limit thereof is preferably 20 nm or more, more preferably 55 nm or more, still more preferably 60 nm or more, and particularly preferably 70 nm or more.

After the transferring, the layer of high refractive index may be sandwiched between a transparent electrode pattern (preferably, an ITO pattern) and the photosensitive layer to form a laminate together with the transparent electrode pattern and the photosensitive layer. In this case, by reducing a difference in refractive index between the transparent electrode pattern and the layer of high refractive index and a difference in refractive index between the layer of high refractive index and the photosensitive layer, a light reflection is further reduced. As a result, covering property of the transparent electrode pattern is further improved.

For example, in a case where the transparent electrode pattern, the layer of high refractive index, and the photosensitive layer are laminated in this order, this transparent electrode pattern is less likely to be visually recognized in a case of being viewed from the transparent electrode pattern side.

The refractive index of the layer of high refractive index is preferably adjusted in accordance with the refractive index of the transparent electrode pattern.

For example, in a case where the transparent electrode pattern is formed of an oxide of In and Sn (ITO), the refractive index of the transparent electrode pattern is in a range of 1.8 to 2.0, and the refractive index of the layer of high refractive index is preferably 1.60 or more. The upper limit of the refractive index of the layer of high refractive index in this case is not particularly limited, but is preferably 2.1 or less, more preferably 1.85 or less, still more preferably 1.78 or less, and particularly preferably 1.74 or less.

For example, in a case where the transparent electrode pattern is formed of an oxide of In and Zn (Indium Zinc Oxide; IZO), the refractive index of the transparent electrode pattern is more than 2.0, and the refractive index of the layer of high refractive index is preferably 1.70 to 1.85.

Examples of a method for controlling the refractive index of the layer of high refractive index include a method using a resin having a predetermined refractive index alone, a method using a resin and metal oxide particles or metal particles, and a method using a composite body of a metal salt and a resin.

As the type of the metal oxide particles or the metal particles, for example, known metal oxide particles or metal particles can be used. The metal of the metal oxide particles or the metal particles also includes semimetal such as B, Si, Ge, As, Sb, or Te.

From the viewpoint of transparency, for example, an average primary particle diameter of the particles (the metal oxide particles or the metal particles) is preferably 1 to 200 nm and more preferably 3 to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

Specifically, as the metal oxide particles, at least one selected from the group consisting of zirconium oxide particles (ZrO₂ particles), Nb₂O₅ particles, titanium oxide particles (TiO₂ particles), silicon dioxide particles (SiO₂ particles), and composite particles thereof is preferable.

As these metal oxide particles, for example, from the viewpoint that the refractive index of the layer of high refractive index can be easily adjusted to 1.60 or more, at least one selected from the group consisting of zirconium oxide particles and titanium oxide particles is more preferable.

In a case where the layer of high refractive index contains metal oxide particles, the layer of high refractive index may contain only one kind of metal oxide particles, or may include two or more kinds thereof.

From the viewpoint that covering property of a concealed object such as the electrode pattern is improved and visibility of the concealed object can be effectively improved, a content of the particles (metal oxide particles or metal particles) is preferably 1% to 95% by mass, more preferably 20% to 90% by mass, and still more preferably 40% to 85% by mass with respect to the total mass of the layer of high refractive index.

In a case where titanium oxide is used as the metal oxide particles, the content of the titanium oxide particles is preferably 1% to 95% by mass, more preferably 20% to 90% by mass, and still more preferably 40% to 85% by mass with respect to the total mass of the layer of high refractive index.

Examples of a commercially available product of the metal oxide particles include calcined zirconium oxide particles (manufactured by CIK-Nano Tek., product name: ZRPGM15WT %-F04), calcined zirconium oxide particles (manufactured by CIK-Nano Tek., product name: ZRPGM15WT %-F74), calcined zirconium oxide particles (manufactured by CIK-Nano Tek., product name: ZRPGM15WT %-F75), calcined zirconium oxide particles (manufactured by CIK-Nano Tek., product name: ZRPGM15WT %-F76), zirconium oxide particles (NanoUse OZ-S30M, manufactured by Nissan Chemical Corporation), and zirconium oxide particles (NanoUse OZ-S30K, manufactured by Nissan Chemical Corporation).

The layer of high refractive index preferably contains at least one selected from the group consisting of inorganic particles (the metal oxide particles or the metal particles) having a refractive index 1.50 or more (more preferably 1.55 or more and still more preferably 1.60 or more), a resin having a refractive index 1.50 or more (more preferably 1.55 or more and still more preferably 1.60 or more), and a polymerizable compound having a refractive index 1.50 or more (more preferably 1.55 or more and still more preferably 1.60 or more).

According to this aspect, the refractive index of the layer of high refractive index is easily adjusted to 1.50 or more (more preferably 1.55 or more and particularly preferably 1.60 or more).

In addition, the layer of high refractive index preferably contains a binder polymer, a polymerizable monomer, and particles.

Examples of the various components contained in the layer of high refractive index include various components of a curable transparent resin layer, described in paragraphs 0019 to 0040 and 0144 to 0150 of JP2014-108541A, various components of a transparent layer, described in paragraphs 0024 to 0035 and 0110 to 0112 of JP2014-010814A, and various components of a composition having a ammonium salt, described in paragraphs 0034 to 0056 of WO2016/009980A.

In addition, it is also preferable that the layer of high refractive index contains a metal oxidation inhibitor.

In a case where the layer of high refractive index contains a metal oxidation inhibitor, during transferring the layer of high refractive index onto the base material, a member that is in direct contact with the layer of high refractive index (for example, a conductive member formed on the base material, or the like) can be surface-treated. This surface treatment imparts a metal oxide inhibiting function (protection properties) with respect to the member that is in direct contact with the layer of high refractive index.

The metal oxidation inhibitor is preferably a compound having an aromatic ring including a nitrogen atom. The compound having an aromatic ring including a nitrogen atom may have a substituent.

The aromatic ring including a nitrogen atom is preferably a fused ring of an imidazole ring, a triazole ring, a tetrazole ring, a thiazole ring, or a thiadiazole ring, and another aromatic ring, and more preferably a fused ring of an imidazole ring, a triazole ring, or a tetrazole ring, and another aromatic ring.

The “another aromatic ring” forming the fused ring may be a homocyclic ring or a heterocyclic ring; and is preferably a homocyclic ring, more preferably a benzene ring or a naphthalene ring, and still more preferably a benzene ring.

As the metal oxidation inhibitor, imidazole, benzimidazole, tetrazole, 5-amino-1H-tetrazole, mercaptothiadiazole, or benzotriazole is preferable, and imidazole, benzimidazole, 5-amino-1H-tetrazole, or benzotriazole is more preferable.

Examples of a commercially available product of the metal oxidation inhibitor include BT120 (manufactured by JOHOKU CHEMICAL CO., LTD.) including benzotriazole.

In a case where the layer of high refractive index contains a metal oxidation inhibitor, a content of the metal oxidation inhibitor is preferably 0.1% to 20% by mass, more preferably 0.5% to 10% by mass, and still more preferably 1% to 5% by mass with respect to the total mass of the layer of high refractive index.

The layer of high refractive index may contain a component other than the above-described components.

Examples of other components which can be contained in the layer of high refractive index include components same as those which can be contained in the photosensitive layer. The layer of high refractive index also preferably contains a surfactant.

Examples of a method of forming the layer of high refractive index include a known forming method.

Examples of the method of forming the layer of high refractive index include a forming method in which a composition for forming the layer of high refractive index in an aspect of including an aqueous solvent is applied onto the above-described photosensitive layer which has been formed on the temporary support, and the composition is dried as necessary.

The composition for forming the layer of high refractive index can contain various components of the above-described layer of high refractive index.

In addition, as the composition for forming the layer of high refractive index, a composition containing an ammonium salt, described in paragraphs 0034 to 0056 of WO2016/009980A, is also preferable.

The layer of high refractive index is preferably achromatic. Specifically, in CIE1976 (L*a*b*) color space of the total reflection (incidence angle: 8°, light source: D-65 (visual field: 2°)), the L* is preferably 10 to 90, the a* is preferably −1.0 to 1.0, and the b* is preferably −1.0 to 1.0.

### <Other Layers>

Examples of other layers include layers described in paragraphs 0189 to 0193 of JP2014-085643A and paragraphs 0194 to 0196 of JP2014-085643A, the contents of which are incorporated herein by reference.

### <Method for Manufacturing Transfer Film>

As a method for manufacturing the transfer film, a known manufacturing method can be adopted.

The method for manufacturing the transfer film preferably includes a step of forming a photosensitive layer by applying and drying a photosensitive material including a solvent on a temporary support, and more preferably includes a step of further disposing a cover film on the photosensitive layer after the step of forming the photosensitive layer.

In addition, after the step of forming the photosensitive layer, a step of forming the layer of high refractive index by applying and drying a composition for forming the layer of high refractive index may be included. In this case, after the step of forming the above-described layer of high refractive index, it is preferable to further include a step of disposing a cover film on the above-described layer of high refractive index.

### [Method for Forming Photosensitive Layer]

The photosensitive layer can be formed by preparing the above-described photosensitive material containing the solvent, and applying and drying the photosensitive material. Each of the various components may be dissolved in the solvent in advance to prepare a solution, and the obtained solutions may be mixed with each other at a predetermined proportion. In addition, the above-described photosensitive material is preferably filtered using a filter having a pore diameter of 0.2 to 30 m, or the like.

The photosensitive layer can be formed by applying the photosensitive material onto a temporary support or a cover film, and drying the photosensitive material.

Examples of the applying method include known methods such as a slit coating, a spin coating, a curtain coating, and an inkjet coating.

In addition, in a case where other layers described later are formed on the temporary support or the cover film, the photosensitive layer may be formed on the other layers.

### [Laminate]

The laminate according to the embodiment of the present invention preferably includes a base material and a protective film.

The laminate preferably includes a substrate having a conductive layer and a protective film in this order, and more preferably includes a substrate, an electrode, and a protective film in this order.

The above-described protective film is as described above.

### [Base Material]

Examples of the base material include a glass substrate, a silicon substrate, a resin substrate, and a substrate having a conductive layer. Examples of the substrate included in the substrate having a conductive layer include a glass substrate, a silicon substrate, and a resin substrate.

The above-described base material is preferably transparent.

A refractive index of the above-described base material is preferably 1.50 to 1.52.

The above-described base material may be composed of a translucent substrate such as a glass substrate.

Examples of the translucent substrate include tempered glass (gorilla glass, manufactured by Corning Incorporated and the like).

As a material constituting the above-described base material, materials described in JP2010-086684A, JP2010-152809A, and JP2010-257492A are preferable.

As the resin substrate, a resin film having a small optical distortion and/or a high transparency is preferable. Examples of a material constituting the resin substrate include polyethylene terephthalate (PET), polyethylene naphthalate, polycarbonate, triacetyl cellulose, and a cycloolefin polymer.

As the substrate included in the substrate having a conductive layer, from the viewpoint of manufacturing by roll-to-roll method, a resin substrate is preferable and a resin film is more preferable.

Examples of the conductive layer include any conductive layer used for general circuit wiring or touch panel wiring. As the conductive layer, an electrode is preferable.

The conductive layer is preferably a transparent layer. The conductive layer may have a patterned shape.

As the conductive layer, from the viewpoint of conductivity and fine line formability, one or more layers selected from the group consisting of a metal layer, a conductive metal oxide layer, a graphene layer, a carbon nanotube layer, and a conductive polymer layer are preferable, a metal layer is more preferable, and a copper layer or a silver layer is still more preferable.

Examples of a material constituting the conductive layer include a simple substance of metal and a conductive metal oxide.

Examples of the simple substance of metal include aluminum, zinc, copper, iron, nickel, chromium, molybdenum, silver, and gold.

Examples of the conductive metal oxide include indium tin oxide (ITO), indium zinc oxide (IZO), and SiO₂. The “conductive” means that a volume resistivity is less than 1×10⁶ Ω·cm, and the volume resistivity is preferably less than 1×10⁴ Ω·cm.

In addition, the conductive layer in the substrate having a conductive layer may be one layer or two or more layers. In a case where the substrate having a conductive layer includes two or more conductive layers, it is preferable that each conductive layer is a conductive layer formed of different materials, and it is preferable to contain a conductive metal oxide.

The conductive layer is preferably an electrode pattern corresponding to a sensor in a visual recognition portion used for a capacitive touch panel or a wiring line for a peripheral wiring portion.

### [Method for Manufacturing Laminate]

Examples of a method for manufacturing the laminate include a known manufacturing method.

Specifically, it is preferable to include a step of forming a photosensitive layer on a base material, a step of exposing the photosensitive layer in a patterned manner, and a step of developing the exposed photosensitive layer (alkali development or organic solvent development). In a case where the above-described development is an organic solvent development, it is preferable to include a step of further exposing the obtained pattern.

Hereinafter, embodiments of the method for manufacturing the laminate will be described.

### Embodiment 1

The method for manufacturing the laminate according to an embodiment 1 includes steps X1 to X3.
Step X1: step of forming a photosensitive layer on a base material
Step X2: step of exposing the photosensitive layer in a patterned manner
Step X3: step of developing the photosensitive layer with a developer (an alkali developer or an organic solvent-based developer)

The above-described step X2 corresponds to a step of reducing the content of the acid group included in the polymer P in the photosensitive layer by exposure.

In a case where the developer in the above-described step X3 is an organic solvent-based developer, it is preferable that a step X4 is further provided after the step X3.

In a case where an alkali developer is used as the developer in the step X3, it is preferable that the photosensitive layer included in the transfer film is formed of the photosensitive material of the embodiment X-1-a1 or the embodiment X-1-a2. In a case where an organic solvent-based developer is used as the developer in the step X3, it is preferable that the photosensitive layer included in the transfer film is formed of the photosensitive material of the embodiment X-1-a1.

### <Step X1>

The step X1 is a step of forming a photosensitive layer on a base material. More specifically, a step of forming a photosensitive layer on a base material using the above-described photosensitive material or the above-described transfer film is preferable.

Examples of a method of forming the photosensitive layer using the photosensitive material include a method of applying the photosensitive material onto the base material and, as necessary, drying the coating film to form the photosensitive layer on the base material.

In addition, as the method of forming the photosensitive layer using the transfer film, the step X1 is preferably a step of bringing a surface of the photosensitive layer in the transfer film on an opposite side of the temporary support side into contact with the base material to bond the transfer film and the base material. Such a step is also particularly referred to as a step X1b.

The step X1b is preferably a step of performing bonding by pressurization using a roll or the like and by heating. Specific examples thereof include a step of performing bonding using a laminator such as a vacuum laminator and an auto-cut laminator.

In the step X1b, it is preferable to use a roll-to-roll method. In a case where the roll-to-roll method is used, as the substrate having a conductive layer, a resin film having a conductive layer is preferable.

The “roll-to-roll method” refers to a method in which, as the base material, a base material which can be wound up and unwound is used, a step (hereinafter, also referred to as an “unwinding step”) of unwinding the base material before any of the steps in the method for manufacturing the laminate, a step (hereinafter, also referred to as a “winding step”) of winding the base material is included after any of the steps, and at least one of the steps (preferably, all steps or all steps other than the heating step) is performed while transporting the base material.

As an unwinding method in the unwinding step and a winding method in the winding step, for example, a known method can be used in the manufacturing method to which the roll-to-roll method is adopted.

### <Step X2>

The step X2 is a step of exposing the photosensitive layer in a patterned manner after the above-described step X1.

The step X2 corresponds to a step of reducing the content of the acid group included in the polymer P in the photosensitive layer by exposure. Specifically, it is preferable that, by using light having a wavelength which excites the compound B and/or a group derived from the compound B included in the polymer P in the photosensitive layer, the photosensitive layer is exposed in a patterned manner.

Arrangement and size of the pattern in the step X2 are not particularly limited.

For example, in a case where the method for manufacturing the laminate according to the embodiment 1 is adopted to the manufacturing of a circuit wiring, from the viewpoint of improving display quality of a display device (for example, a touch panel) including an input device having the circuit wiring manufactured by the method for manufacturing the laminate according to the embodiment 1, and viewpoint of reducing an area occupied by a lead-out wiring as much as possible, at least a part of the pattern (in particular, a portion corresponding to a portion of the electrode pattern of the touch panel and the lead-out wiring) is preferably a thin line having a width of 100 μm or less, and more preferably a thin line having a width of 70 μm or less.

A light source of the exposure light is not particularly limited as long as it can emit light in a wavelength range capable of reducing the content of the acid group included in the polymer P in the photosensitive layer.

Specifically, a light source which can emit light having a wavelength which excites the compound B and/or a group derived from the compound B included in the polymer P in the photosensitive layer (for example, light having a wavelength of 254 nm, a wavelength of 313 nm, a wavelength of 365 nm, a wavelength of 405 nm, or the like) is preferable. Examples of the above-described light source include an ultra-high pressure mercury lamp, a high pressure mercury lamp, a metal halide lamp, and a light emitting diode (LED).

An exposure amount is preferably 10 to 10,000 mJ/cm² and more preferably 50 to 3,000 mJ/cm².

In the step X2, the temporary support may be peeled off from the photosensitive layer and then the pattern exposure may be performed, or before peeling off the temporary support, the pattern exposure may be performed through the temporary support and then the temporary support may be peeled off. In order to prevent mask contamination due to contact between the photosensitive layer and the mask and to avoid an influence of foreign substance adhering to the mask on the exposure, it is preferable to perform the pattern exposure without peeling off the temporary support. The pattern exposure may be an exposure through a mask or a direct exposure using a laser or the like.

Before the step X3 described later, the temporary support is peeled off from the photosensitive layer.

### Step X3

The step X3 is a step of, after the above-described step X2, developing the photosensitive layer exposed in a patterned manner with a developer (alkali developer or organic solvent-based developer).

By reducing the content of the acid group in the photosensitive layer of the exposed portion, a difference in solubility (dissolution contrast) in the developer may occur between the exposed portion and the non-exposed portion of the photosensitive layer exposed in a patterned manner. By forming the dissolution contrast in the photosensitive layer, it is possible to form a pattern in the step X3. In a case where the developer in the above-described step X3 is an alkali developer, the non-exposed portion is removed and a negative pattern is formed by performing the above-described step X3. On the other hand, in a case where the developer in the above-described step X3 is an organic solvent-based developer, the exposed portion is removed and a positive pattern is formed by performing the above-described step X3. For the obtained positive pattern, it is necessary to perform a treatment for reducing the content of the acid group included in the polymer A by the step X4 described later.

### (Alkali Developer)

The alkali developer is not particularly limited as long as it is a liquid exhibiting alkalinity which can remove the non-exposed portion of the photosensitive layer.

Examples of the alkali developer include a known developer such as the developer described in JP1993-072724A (JP-H5-072724A).

As the alkali developer, an alkali aqueous solution-based developer containing a compound having a pKa of 7 to 13 at a concentration of 0.05 to 5 mol/L is preferable.

In addition, the alkali developer may further contain a water-soluble organic solvent, a surfactant, and the like. As the alkali developer, for example, developers described in paragraph 0194 of WO2015/093271A are preferable.

A content of the water in the alkali developer is preferably 50% by mass or more, more preferably 60% by mass or more, still more preferably 85% by mass or more, particularly preferably 90% by mass or more, and most preferably 95% by mass or more with respect to the total mass of the alkali developer. The upper limit thereof is, for example, less than 100% by mass.

### (Organic Solvent-Based Developer)

The organic solvent-based developer is not particularly limited as long as it is an organic solvent which can remove the exposed portion of the photosensitive layer.

Examples of the organic solvent-based developer include developers including an organic solvent such as a ketone-based solvent, an ester-based solvent, an alcohol-based solvent, an amide-based solvent, an ether-based solvent, and a hydrocarbon-based solvent.

The organic solvent-based developer may include one kind or two or more kinds of organic solvents.

In addition, the organic solvent-based developer may be a mixed solution of the above-described organic solvent with an organic solvent other than the above-described organic solvent, and/or water.

A content of water in the organic solvent-based developer is preferably less than 10% by mass, more preferably less than 1% by mass, and still more preferably substantially 0% by mass with respect to the total mass of the organic solvent-based developer.

A content of the organic solvent in the organic solvent-based developer is preferably 50% by mass or more, more preferably 60% by mass or more, still more preferably 85% by mass or more, particularly preferably 90% by mass or more, and most preferably 95% by mass or more with respect to the total mass of the organic solvent-based developer. The upper limit thereof is, for example, 100% by mass or less.

Examples of the developing method include puddle development, shower development, spin development, and dip development. The above-described shower development is a development method of spraying the developer onto the photosensitive layer which has been exposed in a patterned manner with a shower to remove a portion as a removal target. In addition, after the development, a development residue may be removed while further spraying a detergent or the like with a shower and rubbing the photosensitive layer with a brush or the like.

The temperature of the developer during the development is preferably 20° C. to 40° C.

The method for manufacturing the laminate according to the embodiment 1 may include a post-baking step of heat-treating the pattern formed by the above-described step X2.

The environment in a case of performing the post-baking is preferably 8.1 kPa or more and more preferably 50.66 kPa or more. The upper limit thereof is preferably 121.6 kPa or less, more preferably 111.46 kPa or less, and still more preferably 101.3 kPa or less.

The temperature of the post-baking is preferably 80° C. to 250° C., more preferably 110° C. to 170° C., and still more preferably 130° C. to 150° C.

The time of the post-baking is preferably 1 to 60 minutes, more preferably 2 to 50 minutes, and still more preferably 5 to 40 minutes.

The post-baking may be performed in an air environment or in a nitrogen purged environment.

### Step X4

The method for manufacturing the laminate according to the embodiment 1 may include a step X4.

Step X4: step of further exposing the pattern formed by the development after the developing step of the step X3

In a case where the developer in the above-described step X3 is an organic solvent-based developer, it is preferable that the step X4 is performed on the obtained positive pattern.

The step X4 corresponds to a step of exposing the positive pattern obtained in the step X3 to reduce the content of the acid group included in the polymer P.

The exposure method, and the light source and of the exposure amount of the exposure light in the step X4 have the same definitions as the exposure method, and the light source and the exposure amount of the exposure light in the step X1, respectively, and suitable aspects thereof are also the same.

### Embodiment 2

The method for manufacturing the laminate according to an embodiment 2 includes a step Y1, a step Y2P, and a step Y3 in this order, and further includes a step Y2Q between the step Y2P and the step Y3 or after the step Y3.
Step Y1: step of forming a photosensitive layer on a base material
Step Y2P: step of exposing the photosensitive layer
Step Y3: step of developing the photosensitive layer with a developer
Step Y2Q: step of further exposing the exposed photosensitive layer in the step Y2P

The photosensitive layer included in the transfer film in the method for manufacturing the laminate according to the embodiment 2 is preferably formed of the photosensitive material of the embodiment X-1-a3.

Hereinafter, the method for manufacturing the laminate according to the embodiment 2 will be described in detail.

The step Y1 and the step Y3 have the same definitions as the step X1 and the step X3, respectively, and suitable aspects thereof are also the same. The step Y3 may be performed after the step Y2P, or may be performed between the step Y2P and the step Y2Q.

A post-baking step which can be further provided in the method for manufacturing the laminate according to the embodiment 1 may be further provided after the step Y3. In a case where the step Y3 is performed between the step Y2P and the step Y2Q, the post-baking step may be performed before the step Y2Q, and may be performed after the step Y2Q as long as it is performed after the step Y3.

### Step Y2P and step Y2Q

The step Y2P is a step of exposing the photosensitive layer, and the step Y2Q is a step of further exposing the photosensitive layer exposed in the step Y2P.

One of the step Y2P or the step Y2Q is an exposure for mainly reducing the content of the acid group included in the polymer P by the exposure, and the other one of the step Y2P or the step Y2Q is an exposure for mainly causing a polymerization reaction of the polymerizable compound based on the photopolymerization initiator. In addition, the step Y2P and the step Y2Q may be either the entire exposure or the pattern exposure, but any one of the step Y2P or the step Y2Q is the pattern exposure.

For example, in a case where the step Y2P is a pattern exposure for reducing the content of the acid group included in the polymer P by the exposure, the developer used in the step Y3 may be an alkali developer or an organic solvent-based developer.

In a case where an organic solvent-based developer is used as the developer, the step Y2Q is performed after the step Y3, and in the formed pattern, the polymerization reaction of the polymerizable compound based on the photopolymerization initiator occurs, and the content of the acid group included in the polymer P is reduced.

In addition, for example, in a case where the step Y2P is a pattern exposure for causing a polymerization reaction of the polymerizable compound based on the photopolymerization initiator, the developer used in the step Y3 is preferably an alkali developer. In the above case, the step Y2Q may be performed before the step Y3 or after the step Y3, and the step Y2Q in a case of being performed before the step Y3 is preferably a pattern exposure.

As the exposure method, and the light source and of the exposure amount of the exposure light in the step Y2P and the step Y2Q, for example, the exposure method, and the light source and the exposure amount of the exposure light in the step X1 may be used, respectively.

In the exposure for reducing the content of the acid group included in the polymer P in the photosensitive layer by the exposure, an exposure amount is preferably 10 to 10,000 mJ/cm² and more preferably 50 to 3,000 mJ/cm².

In the exposure for causing a reaction of the polymerizable compound based on the photopolymerization initiator in the photosensitive layer, an exposure amount is preferably 5 to 200 mJ/cm² and more preferably 10 to 150 mJ/cm².

In the step Y2P and the step Y2Q, same as the step X2, the temporary support may be peeled off from the photosensitive layer and then the pattern exposure may be performed, or before peeling off the temporary support, the pattern exposure may be performed through the temporary support and then the temporary support may be peeled off. It is preferable to carry out the pattern exposure without peeling off the temporary support. The pattern exposure may be an exposure through a mask or a direct exposure using a laser or the like.

Arrangement and size of the pattern in the step Y2P and the step Y2Q are not particularly limited.

For example, the description regarding the arrangement and the size of the pattern in the above-mentioned step X2 can be referred to.

### Other Embodiments

In the method for manufacturing the laminate, it is also preferable to use a substrate having two or more conductive layers on both surfaces, and sequentially or simultaneously form patterns on the conductive layers formed on both surfaces. With the above-described configuration, it is possible to form a first conductive pattern on one surface of the substrate and form a second conductive pattern on the other surface. It is also preferable to form the patterns from both surfaces of the base material by the roll-to-roll.

### Other Steps

The method for manufacturing the laminate may include other steps in addition to the above-described steps.

### <Cover Film Peeling Step>

In a case where the transfer film includes a cover film, it is preferable to include a step of peeling off the cover film of the transfer film. As a method of peeling off the cover film, and a known method can be adopted.

### <Step of Reducing Visible Light Reflectivity>

In a case where the base material has a conductive layer, the method for manufacturing the laminate may further include a step of performing a treatment of reducing the visible light reflectivity of the conductive layer. In a case where the above-described substrate has two or more conductive layers, the treatment of reducing the visible light reflectivity may be performed on some or all of the conductive layers.

Examples of the treatment of reducing the visible light reflectivity include an oxidation treatment. Specific examples thereof include a treatment in which, by oxidizing copper to copper oxide, the visible light reflectivity of the conductive layer is reduced due to blackening.

Examples of a suitable aspect of the treatment of reducing the visible light reflectivity include the descriptions in paragraphs 0017 to 0025 of JP2014-150118A, and paragraphs 0041, 0042, 0048, and 0058 of JP2013-206315A, the contents of which are incorporated in the present specification.

### [Method for Manufacturing Circuit Wiring]

Examples of a method for manufacturing a circuit wiring include a known method for manufacturing a circuit wiring.

Specifically, a method for manufacturing a circuit wiring, including a photosensitive layer forming step, a first exposing step, a developing step, and an etching step in this order, is preferable.

Photosensitive layer forming step: step of forming a photosensitive layer on a substrate having a conductive layer, using a photosensitive material or a transfer film

First exposing step: step of exposing the photosensitive layer in a patterned manner

Developing step: step of developing the exposed photosensitive layer with an alkali developer to form a patterned etching resist film

Etching step: step of subjecting the above-described conductive layer in a region where the etching resist film is not disposed to an etching treatment

The photosensitive layer forming step, the first exposing step, and the developing step can be performed by the same procedures as in the step X1, the step X2, and the step X3 in the method for manufacturing the laminate according to the embodiment 1, respectively.

The substrate having a conductive layer has the same definition as the substrate having a conductive layer, which is used in the step X1, and a suitable aspect thereof is also the same.

In the method for manufacturing a circuit wiring according to the present invention, it is also preferable that the steps from the bonding step to the etching step described above are regarded as one set and repeated a plurality of times.

The film used as the etching resist film can also be used as a protective film (permanent film) for the formed circuit wiring.

### <Etching Step>

The etching step is a step of subjecting the above-described conductive layer in a region where the patterned etching resist film is not disposed to an etching treatment.

Examples of the etching treatment include a method by wet etching, which is described in paragraphs 0048 to 0054 of JP2010-152155A, and a method by dry etching such as a known plasma etching.

Examples of the above-described wet etching include an etching method by immersing in a known etchant. The etchant may be an acidic etchant or an alkaline etchant.

Examples of the acidic etchant include aqueous solutions of acidic component alone, such as hydrochloric acid, sulfuric acid, hydrofluoric acid, and phosphoric acid, and mixed aqueous solutions of an acidic component and a salt such as ferric chloride, ammonium fluoride, and potassium permanganate. The acidic component may be used alone or in combination of two or more kinds thereof.

Examples of the alkaline etchant include aqueous solutions of alkaline component alone, such as sodium hydroxide, potassium hydroxide, ammonia, organic amine, and a salt of organic amine (for example, tetramethylammonium hydroxide), and mixed aqueous solutions of an alkaline component and a salt such as potassium permanganate. The alkaline component may be used alone or in combination of two or more kinds thereof.

A temperature of the etchant is preferably 45° C. or lower.

The pattern formed by the step X3 or the step X4 and the step Y3, which is used as the etching resist film, preferably exhibits particularly excellent resistance to the acidic and alkaline etchant in a temperature of 45° C. or lower. With the above-described configuration, it is possible to prevent the etching resist film from peeling off during the etching step, and it is possible to selectively etch a portion where the etching resist film does not exist.

After the etching step, in order to prevent contamination of the process line, a washing step of washing the etched substrate and a drying step of drying the washed substrate may be performed as necessary.

### [Method for Manufacturing Touch Panel]

Examples of a method for manufacturing a touch panel include a known method for manufacturing a touch panel.

Specifically, a method for manufacturing a touch panel, including a photosensitive layer forming step, a first exposing step, and a protective film or insulating film forming step in this order, is preferable.

Photosensitive layer forming step: step of forming a photosensitive layer on a conductive layer in a substrate having a conductive layer (preferably, a patterned conductive layer; specifically, a touch panel electrode pattern or a conductive pattern such as a wiring line), using a photosensitive material or a transfer film

First exposing step: step of exposing the photosensitive layer in a patterned manner

Protective film or insulating film forming step: step of developing the exposed photosensitive layer with an alkali developer to form a patterned protective film or insulating film of the above-described conductive layer

The protective film has a function as a film which protects the surface of the conductive layer. In addition, the insulating film has a function as an interlayer insulating film between conductive layers. In a case of forming the insulating film of the conductive layer, it is preferable that the method for manufacturing a touch panel according to the present invention further includes a step of forming a conductive layer (preferably, a patterned conductive layer; specifically, a touch panel electrode pattern or a conductive pattern such as a wiring line) on the formed insulating film.

The photosensitive layer forming step and the first exposing step can be performed by the same procedures as in the step X1, the step X2, and the step X3 in the method for manufacturing the laminate according to the embodiment 1, respectively.

The substrate having a conductive layer has the same definition as the substrate having a conductive layer, which is used in the step X1, and a suitable aspect thereof is also the same.

The touch panel manufactured by the above-described method for manufacturing a touch panel preferably includes a transparent substrate, an electrode, and a protective film (protective layer).

Examples of a detection method in the above-described touch panel include any known method such as a resistive film method, a capacitance method, an ultrasonic method, an electromagnetic induction method, and an optical method; and a capacitance method is preferable.

Examples of the touch panel type include an in-cell type (for example, FIGS. 5 to 8 of JP2012-517051A, and the like), an on-cell type (for example, FIG. 19 of JP2013-168125A, FIGS. 1 and 5 of JP2012-089102A, and the like), an one glass solution (OGS) type, a touch-on-lens (TOL) type (for example, FIG. 2 of JP2013-054727A, and the like), other configurations (for example, FIG. 6 of JP2013-164871A, and the like), and various out-cell types (so-called GG, G1-G2, GFF, GF2, GF1, G1F, and the like).

### EXAMPLES

Hereinafter, the present invention will be described in more detail with reference to Examples. The material, the amount used, the proportion, the process contents, the process procedure, and the like shown in the following examples can be appropriately changed, within a range not departing from the gist of the present invention. Therefore, the scope of the present invention is not limited to the specific examples described below. “Part” and “%” are based on mass unless otherwise specified.

In the following examples, a weight-average molecular weight of a resin (polymer) is a weight-average molecular weight obtained by performing polystyrene conversion of a value measured by gel permeation chromatography (GPC).

In the following Examples, unless otherwise specified, a high-pressure mercury lamp (H03-L31) manufactured by Eye Graphics Co., Ltd. was used. The above-described high-pressure mercury lamp has strong line spectrum at a wavelength of 254 nm, a wavelength of 313 nm, a wavelength of 405 nm, and a wavelength of 436 nm, with a wavelength of 365 nm as a main wavelength.

### [Production of Protective Film]

Various components were mixed with the content shown in the table below, followed by stirring at 250 rpm for 20 minutes to prepare photosensitive materials 1 to 7. The obtained photosensitive materials 1 to 7 were each spin-coated and dried on a 10 cm-square copper substrate so that a thickness after drying was 3.0 m. The obtained coating film was exposed using a high-pressure mercury lamp through a mask, so that a frame portion (width: 1 cm) of the above-described copper substrate was shielded from light. Furthermore, development was carried out at 23° C. for 50 seconds using a 1% by mass sodium carbonate aqueous solution to obtain an 8 cm-square film on the copper substrate. An integrated exposure amount in the exposure, which was measured with a 365 nm wavelength illuminance meter, was 1,000 mJ/cm². Thereafter, post-baking was carried out in an oven at 145° C. for 25 minutes to produce protective films 1 to 7 formed on the copper substrate.

### [Various Components of Photosensitive Material]

### <Polymer P1>

Propylene glycol monomethyl ether acetate (PGMEA) (60 parts) and propylene glycol monomethyl ether (PGME) (240 parts) were poured into a flask having a capacity of 2 L, and the temperature was raised to 90° C. while stirring at 250 rpm.

Styrene (80 parts) and acrylic acid (20 parts) were mixed and diluted with PGMEA (60 parts) to obtain a dropping liquid (1).

V-601 (dimethyl 2,2′-azobis(2-methylpropionate)) (9.637 parts) was dissolved in PGMEA (136.56 parts) to obtain the dropping liquid (2).

The above-described dropping liquid (1) and the above-described dropping liquid (2) were simultaneously added dropwise to the above-described flask having a capacity of 2 L (specifically, the flask having a capacity of 2 L containing the liquids heated to 90° C.) over 3 hours. After the dropwise addition, V-601 (2.401 parts) was added to the flask three times every hour. Thereafter, stirring was further carried out at 90° C. for 3 hours. By the above-described procedure, a solution containing a polymer P1 was obtained (solid content: 36.3% by mass).

### <Polymer P2>

PGMEA (60 parts) and PGME (240 parts) were poured into a flask having a capacity of 2 L, and the temperature was raised to 90° C. while stirring at 250 rpm.

Styrene (59 parts), 9-vinylacridine (20 parts), and acrylic acid (21 parts) were mixed and diluted with PGMEA (60 parts) to obtain a dropping liquid (1).

V-601 (dimethyl 2,2′-azobis(2-methylpropionate)) (9.637 parts) was dissolved in PGMEA (136.56 parts) to obtain the dropping liquid (2).

The dropping liquid (1) and the dropping liquid (2) were simultaneously added dropwise to the above-described flask having a capacity of 2 L (specifically, the flask having a capacity of 2 L containing the liquids heated to 90° C.) over 3 hours. After the dropwise addition, V-601 (2.401 parts) was added to the flask three times every hour. Thereafter, stirring was further carried out at 90° C. for 3 hours. By the above-described procedure, a solution containing a polymer P2 was obtained (solid content: 36.3% by mass).

### <Polymer P3>

Propylene glycol monomethyl ether acetate (PGMEA) (60 parts) and propylene glycol monomethyl ether (PGME) (240 parts) were poured into a flask having a capacity of 2 L, and the temperature was raised to 90° C. while stirring at 250 rpm.

Styrene (85 parts) and acrylic acid (15 parts) were mixed and diluted with PGMEA (60 parts) to obtain a dropping liquid (1).

V-601 (dimethyl 2,2′-azobis(2-methylpropionate)) (9.637 parts) was dissolved in PGMEA (136.56 parts) to obtain the dropping liquid (2).

The above-described dropping liquid (1) and the above-described dropping liquid (2) were simultaneously added dropwise to the above-described flask having a capacity of 2 L (specifically, the flask having a capacity of 2 L containing the liquids heated to 90° C.) over 3 hours. After the dropwise addition, V-601 (2.401 parts) was added to the flask three times every hour. Thereafter, stirring was further carried out at 90° C. for 3 hours. By the above-described procedure, a solution containing a polymer P3 was obtained (solid content: 36.3% by mass).

Structures of the polymers P1 and P2 are shown below.

The composition of each repeating unit in the polymer P1 was 80% by mass and 20% by mass in this order from the left. In addition, the composition of each repeating unit in the polymer P2 was 59% by mass, 20% by mass, and 21% by mass in this order from the left.

In addition, the polymer P3 included the same type of repeating units as the polymer P1, represented by the following structural formula, and the composition of each repeating unit was 85% by mass and 15% by mass in this order from the left.

A weight-average molecular weight of the polymer P1 was 12,000, a weight-average molecular weight of the polymer P2 was 13,000, and a weight-average molecular weight of P3 was 7,000.

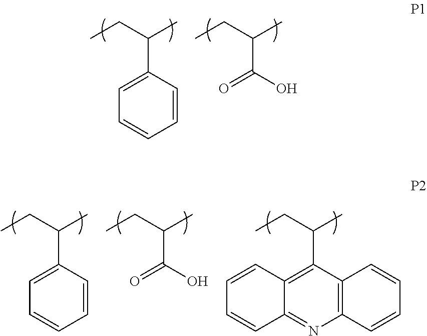

In addition, a protective film of each of Examples and Comparative Examples, which was formed by the above-described procedure, contained any of the following polymers a1 to a4.

The protective films of Examples 1 and 2 contained the polymer a1, the protective films of Examples 3 and 4 contained the polymer a2, the protective film of Example 5 contained the polymer a3, the protective film of Example 6 contained the polymer a3, and the protective film of Comparative Example 1 contained the polymer a4.

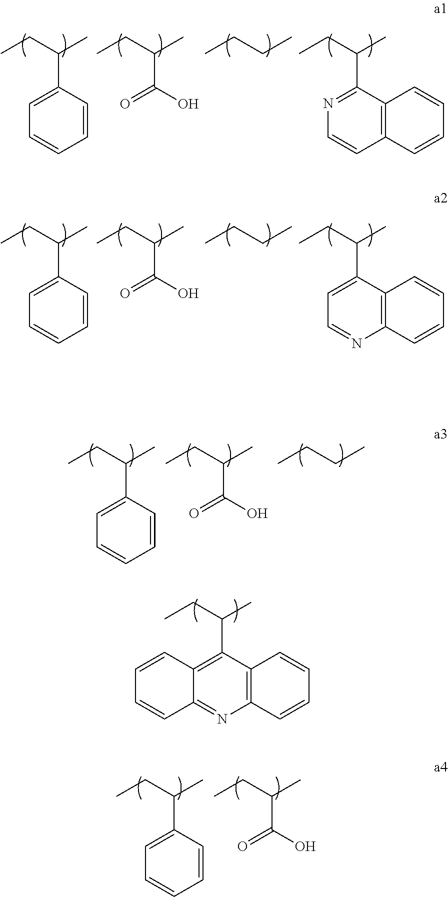

### <Compound B>

Isoquinoline
Quinoline
Acridine

### <Photopolymerization Initiator>

Irgacure OXE01 (manufactured by BASF SE)

### <Polymerizable Compound>

BPE-500 (manufactured by Shin-Nakamura Chemical Co., Ltd.)

### <Solvent>

MEK: methyl ethyl ketone

### [Measurement]

### [Acid Value of Protective Film]

Approximately 20 mg of each the protective films 1 to 7 on the copper substrate was scraped off, and frozen and pulverized, N-methyl-2-pyrrolidone (NMP) (150 μL) was added thereto, and the mixture was stirred in an aqueous solution of lithium carbonate (Li₂CO₃) (1.2 g/100 mL; lithium carbonate was dissolved in ultrapure water and then filtered through a filter) for 6 days. After the stirring, particles were sedimented by ultracentrifugal treatment (140,000 rpm for 30 minutes), the obtained sediment was replaced five times with ultrapure water, and the obtained sediment was dried to obtain an analysis sample.

Using ICP-OES (Optima 7300DV manufactured by PerkinElmer Inc.), an amount of lithium (Li) of the obtained analysis sample was analyzed. The obtained numerical value was divided by the number of atoms of Li (6.941 g/mol) to calculate the amount (mol/g) of acid groups in the protective film, and the obtained numerical value was multiplied by the molecular weight of KOH to calculate the acid value (mgKOH/g) of the protective film.

By carrying out the above-described measurement of the acid value of the protective film 5 times, and removing the maximum value and the minimum value among the obtained measured values for the 5 times, the remaining three measured values were arithmetically averaged, and the obtained arithmetic average value was shown in the table below as the acid value (mgKOH/g) of the protective film of each of Examples and Comparative Examples.

The above-described analysis of the Li amount was carried out according to the following procedure. Approximately 1.5 to 2 mg of the above-described analysis sample was weighed, a 60% by mass of HNO₃ aqueous solution (5 mL) was added thereto, and MW Teflon (registered trademark) ashing (microwave sample decomposition device UltraWAVE max: 260° C.) was performed. Ultrapure water was added to the ashed analysis sample to be 50 mL, and the Li amount was quantified by an absolute calibration curve method using ICP-OES.

### [Specific Maximal Absorption Wavelength]

A total of 30 mg of each the protective films 1 to 7 on the copper substrate was scraped off, mixed with barium sulfate (270 mg), and crushed using an agate mortar so that a particle diameter of a solid powder was 2 m or less, thereby obtaining a sample for measurement. The sample for measurement (approximately 100 mg) was set on a specimen table, and flattened such that a gap was not generated in the measurement range. Next, using a measurement instrument V-7200 (manufactured by JASCO Corporation), diffuse reflectivities of the barium sulfate (standard sample) and the sample for measurement at a wavelength of 300 to 700 nm were measured to obtain a relative reflectivity R of the sample for measurement. Next, the relative reflectivity R (%) obtained by the measurement was converted into K (absorption coefficient)/S (scattering coefficient) based on the following expression.

$$K / S = {( 1 - R )}^{2} / 2 R$$

The above expression is called a Kubelka-Munk function.

By the above-described conversion, a graph of horizontal axis: wavelength and vertical axis: K (absorption coefficient)/S (scattering coefficient) was obtained, and a peak top in a wavelength range of 300 to 400 nm in the graph was defined as the specific maximal absorption wavelength.

### [Rate of Change of K (Absorption Coefficient)/S (Scattering Coefficient) Before and After Heating Treatment]

The specific maximal absorption wavelength was determined according to the same procedure as in [Specific maximal absorption wavelength] described above. K (absorption coefficient)/S (scattering coefficient) at the specific maximal absorption wavelength was obtained, and the obtained K/S was used as K (absorption coefficient)/S (scattering coefficient) at the specific maximal absorption wavelength before a heating treatment.

Next, after heating the protective film at 140° C. for 30 minutes, the above-described K (absorption coefficient)/S (scattering coefficient) at the specific maximal absorption wavelength in a wavelength range of 300 to 400 nm was determined according to the same procedure as described above. The obtained K/S corresponds to K (absorption coefficient)/S (scattering coefficient) at the specific maximal absorption wavelength after the heating treatment.

Next, the rate of change was calculated according to the following expression.

Rate of change (%)=[100×(|K (absorption coefficient)/S (scattering coefficient) at specific maximal absorption wavelength before heating treatment|−|K (absorption coefficient)/S (scattering coefficient) at specific maximal absorption wavelength after heating treatment|)/K (absorption coefficient)/S (scattering coefficient) at specific maximal absorption wavelength before heating treatment]

### Evaluation

### [Adhesiveness]

Regarding each of the protective films 1 to 7 on the copper substrate, a cut of a lattice pattern with a 1 mm square was made on the surface of each protective film opposite to the copper substrate using a cutter knife, and a transparent pressure-sensitive adhesive tape #600 (manufactured by 3M Ltd.) was firmly pressed onto the surface with the cut. The above-described transparent pressure-sensitive adhesive tape pressed was peeled off from each protective film in a direction of 180°. A state of the lattice pattern was observed, and adhesiveness of the protective film was evaluated according to the following evaluation standard. It is noted that the evaluation A and the evaluation B are practically acceptable levels.
A: the entire area of the lattice pattern on the copper substrate after the peeling was 70% or more with respect to the entire area of the lattice pattern on the copper substrate before the peeling.
B: the entire area of the lattice pattern on the copper substrate after the peeling was 35% or more and less than 70% with respect to the entire area of the lattice pattern on the copper substrate before the peeling.
C: the entire area of the lattice pattern on the copper substrate after the peeling was less than 35% with respect to the entire area of the lattice pattern on the copper substrate before the peeling.

### [Moisture-Heat Resistance]

A copper substrate having any one of the protective films 1 to 7 was allowed to stand for a predetermined time in a constant-temperature and constant-humidity tank at 65° C. and 90% RH, a time until the copper substrate was discolored was confirmed, and moisture-heat resistance was evaluated according to the following evaluation standard. The discoloration of the copper substrate was visually confirmed through the protective film.
A: discoloration of the copper substrate was not observed even after 240 hours.
B: discoloration of the copper substrate was not observed after 120 hours, but discoloration of the copper substrate was observed after 240 hours.
C: discoloration of the copper substrate was not observed after 60 hours, but discoloration of the copper substrate was observed after 120 hours.
D: discoloration of the copper substrate was observed after 60 hours.

### Result

In the table, each description indicates the following.

The numerical values in parentheses in the columns of “Polymer P”, “Compound B”, “Polymerizable compound”, and “Solvent” indicate the respective contents (part by mass) thereof. The content of the polymer P indicates a solid content equivalent.

In the table, “-” in the column of “Specific maximal absorption wavelength” indicates that there was no specific maximal absorption wavelength in a wavelength range of 300 to 400 nm.

In the table, the column of “K/S after heating” indicates K (absorption coefficient)/S (scattering coefficient) at the specific maximal absorption wavelength after the heating treatment; and “A” indicates that K/S was 0.01 or more and 4.0 or less, “B” indicates that K/S was more than 4.0, and “C” indicates that K/S was less than 0.01 or that the maximal absorption wavelength was not in the range of 300 to 400 nm.

In the table, the column of “Rate of change” denotes a rate of change, calculated by [Rate of change of K/S before and after heating treatment] described above. In the table, “<10%” indicates less than 10%.

TABLE 2

| | | | | | | | Protective film | | | | | | |
|---|---|---|---|---|---|---|---|---|---|---|---|---|---|
| | | | | | | | | Acid | Specific | | | | |
| | Photosensitive material | | | | | | | value of | maximal | | | Evaluation | |
| | | | | Photo- | | | | protective | absorp- | | | | Moisture- |
| | | | Com- | polymer- | Poly- | | | film | tion | K/S | Rate | Ad- | heat |
| | | | pound | ization | merizable | | | [mgKOH/ | wave- | after | of | hesive- | resis- |
| | Type | Polymer P | B | initiator | compound | Solvent | Type | g] | length | heating | change | ness | tance |
| Example 1 | 1 | Polymer P1 | | — | — | MEK | 1 | 31 | 325 nm | A | <10% | A | A |
| | | (100) | | | | (100) | | | | | | | |
| Example 2 | 2 | Polymer P3 | | — | — | MEK | 2 | 23 | 325 nm | A | <10% | A | A |
| | | (100) | | | | (100) | | | | | | | |
| Example 3 | 3 | Polymer P3 | | — | — | MEK | 3 | 49 | 325 nm | A | <10% | A | A |
| | | (100) | | | | (100) | | | | | | | |
| Example 4 | 4 | Polymer P1 | | — | — | MEK | 4 | 78 | 315 nm | A | <10% | A | B |
| | | (100) | | | | (100) | | | | | | | |
| Example 5 | 5 | Polymer P1 | | — | — | MEK | 5 | 93 | 360 nm | A | <10% | B | B |
| | | (100) | | | | (100) | | | | | | | |
| Example 6 | 6 | Polymer P2 | — | — | — | MEK | 6 | 117 | 360 nm | A | <10% | B | C |
| | | (100) | | | | (100) | | | | | | | |
| Compar- | 7 | Polymer P1 | — | IRGACURE | BPE-500 | MEK | 7 | 128 | — | C | — | C | D |
| ative | | (100) | | OXE01 (2) | (20) | (100) | | | | | | | |
| Example 1 | | | | | | | | | | | | | |

From the evaluation results shown in the table, it was confirmed that the protective film according to the embodiment of the present invention had excellent adhesiveness to an electrode and also had excellent moisture-heat resistance.

In a case where the acid value of the protective film was 100 mgKOH/g or less (preferably, 80 mgKOH/g or less), it was confirmed that the moisture-heat resistance was more excellent.

### EXPLANATION OF REFERENCES

12: temporary support
14: photosensitive layer
16: cover film
100: transfer film

What is claimed is:

1. A protective film for an electrode, comprising:
a polymer A which has a repeating unit A having an acid group,
wherein an acid value of the protective film is 120 mgKOH/g or less,
the protective film has a maximal absorption wavelength in a wavelength range of 300 to 400 nm, and
in a case where the protective film is heated at 140° C. for 30 minutes, a rate of change of K (an absorption coefficient)/S (a scattering coefficient) at the maximal absorption wavelength is 10% or less.

2. The protective film according to claim 1,
wherein the acid value of the protective film is 100 mgKOH/g or less.

3. The protective film according to claim 1,
wherein the acid value of the protective film is 80 mgKOH/g or less.

4. The protective film according to claim 1,
wherein, in the case where the protective film is heated at 140° C. for 30 minutes, the K/S at the maximal absorption wavelength is 4.0 or less.

5. The protective film according to claim 1,
wherein, in the case where the protective film is heated at 140° C. for 30 minutes, the K/S at the maximal absorption wavelength is 0.01 or more.

6. The protective film according to claim 1,
wherein the polymer A has a group formed by removing one hydrogen atom from a nitrogen-containing aromatic compound, and
the nitrogen-containing aromatic compound has a maximal absorption wavelength in the wavelength range of 300 to 400 nm.

7. The protective film according to claim 1,
wherein the polymer A has a group represented by Formula (Zb2), 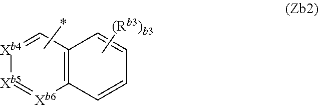
in Formula (Zb2), X^{b4} to X^{b6} each independently represent CR^{b6} or a nitrogen atom, at least one of X^{b4}, X^{b5}, or X^{b6} represents a nitrogen atom, R^{b3} represents an alkyl group, R^{b6} represents a hydrogen atom or an alkyl group, b3 represents an integer of 0 to 4, and * represents a bonding position.

8. The protective film according to claim 1,
wherein the repeating unit A has a repeating unit represented by Formula (a1) or a repeating unit represented by Formula (a2), 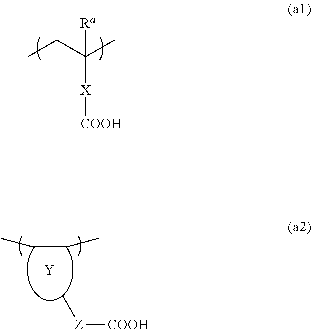
in Formula (a1), R^{a} represents a hydrogen atom or a substituent, and X represents a single bond or a divalent linking group having 1 or more carbon atoms,
in Formula (a2), Y represents a ring group having 2 or more carbon atoms, Z represents a single bond or a divalent linking group, and at least one of Y or Z represents a group having 1 or more carbon atoms.

9. The protective film according to claim 1,
wherein the acid value of the protective film is 5 mgKOH/g or more.

10. A protective film according to claim 1,
wherein the acid value of the protective film is 80 mgKOH/g or less,
in the case where the protective film is heated at 140° C. for 30 minutes, the K/S at the maximal absorption wavelength is 0.01 to 4.0, and
the repeating unit A has a repeating unit represented by Formula (a1) or a repeating unit represented by Formula (a2), 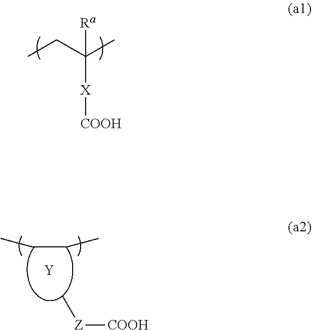
in Formula (a1), R^{a} represents a hydrogen atom or a substituent, and X represents a single bond or a divalent linking group having 1 or more carbon atoms,
in Formula (a2), Y represents a ring group having 2 or more carbon atoms, Z represents a single bond or a divalent linking group, and at least one of Y or Z represents a group having 1 or more carbon atoms.

11. A laminate comprising, in the following order:
a substrate;
an electrode; and
the protective film according to claim 1.
